(19) United States
(12) Patent Application Publication
(10) Pub. No.: US 2025/0120140 A1
(43) Pub. Date: Apr. 10, 2025

(54) INTEGRATED CIRCUIT DEVICES

(71) Applicant: Samsung Electronics Co., Ltd., Suwon-si (KR)

(72) Inventor: Jisoo Oh, Suwon-si (KR)

(21) Appl. No.: 18/743,372

(22) Filed: Jun. 14, 2024

(30) Foreign Application Priority Data
Oct. 6, 2023 (KR) 10-2023-0133770

(51) Int. Cl. H01L 29/06; H01L 27/088; H01L 29/417; H01L 29/423; H01L 29/66; H01L 29/775; H01L 29/786

(52) U.S. Cl. CPC H10D 62/121; H10D 30/43; H10D 30/6729; H10D 30/6735; H10D 30/6757; H10D 64/021; H10D 84/83

(57) ABSTRACT

An integrated circuit device includes a substrate; a fin-type active region that extends in a first horizontal direction on the substrate; a gate line on the fin-type active region, wherein the gate line extends in a second horizontal direction that intersects the first horizontal direction; and a gate dielectric film that is in contact with a lower surface and opposite sidewalls of the gate line, wherein a gate upper surface of the gate line includes a portion that has a decreasing distance from the substrate in a vertical direction as a distance between the portion of the gate upper surface of the gate line and the gate dielectric film in the first horizontal direction decreases.

### REFERENCE TO RELATED APPLICATIONS

This application is based on and claims priority under 35 U.S.C. § 119 to Korean Patent Application No. 10-2023-0133770, filed on Oct. 6, 2023, in the Korean Intellectual Property Office, the disclosure of which is incorporated by reference herein in its entirety.

### BACKGROUND OF THE INVENTION

The inventive concept relates to integrated circuit devices, and more particularly, to integrated circuit devices including a field-effect transistor.

As integrated circuit devices have been rapidly down-scaled in recent years, integrated circuit devices are in need of securing accuracy in operations as well as high operation speeds. In addition, as integrated circuit devices have increasing degrees of integration and have decreasing sizes, there is a need to develop a novel structure capable of improving the performance and reliability of field-effect transistors.

### SUMMARY OF THE INVENTION

The inventive concept provides an integrated circuit device having a structure capable of improving the performance of a transistor and reducing the power consumption thereof by reducing the parasitic capacitance between adjacent conductive regions.

According to an aspect of the inventive concept, there is provided an integrated circuit device including a substrate; a fin-type active region that extends in a first horizontal direction on the substrate; a gate line on the fin-type active region, wherein the gate line extends in a second horizontal direction that intersects the first horizontal direction; and a gate dielectric film that is in contact with a lower surface and opposite sidewalls of the gate line, wherein a gate upper surface of the gate line includes a portion that has a decreasing distance from the substrate in a vertical direction as a distance between the portion of the gate upper surface of the gate line and the gate dielectric film in the first horizontal direction decreases.

According to another aspect of the inventive concept, there is provided an integrated circuit device including a substrate that includes a first device area and a second device area; a first fin-type active region on the substrate in the first device area, wherein the first fin-type active region extends in a first horizontal direction; a first gate line on the first fin-type active region, wherein the first gate line extends in a second horizontal direction that intersects the first horizontal direction, and wherein the first gate line has a first width in the first horizontal direction; a first gate dielectric film that is in contact with a lower surface and opposite sidewalls of the first gate line; a second fin-type active region on the substrate in the second device area, wherein the second fin-type active region extends in the first horizontal direction; a second gate line on the second fin-type active region, wherein the second gate line extends in the second horizontal direction, and wherein the second gate line has a second width that is greater in the first horizontal direction than the first width of the first gate line; and a second gate dielectric film that is in contact with a lower surface and opposite sidewalls of the second gate line, wherein a first gate upper surface of the first gate line includes a portion that has a decreasing distance from the substrate in a vertical direction as a distance between the portion of the first gate upper surface of the first gate line and the first gate dielectric film in the first horizontal direction decreases, and wherein a second gate upper surface of the second gate line includes a portion that has a decreasing distance from the substrate in the vertical direction as a distance between the portion of the second gate upper surface of the second gate line and the second gate dielectric film in the first horizontal direction decreases.

According to another aspect of the inventive concept, there is provided an integrated circuit device including a substrate; a fin-type active region that extends in a first horizontal direction on the substrate; a nanosheet stack on a fin upper surface of the fin-type active region, wherein the nanosheet stack is spaced apart from the fin upper surface in a vertical direction, and wherein the nanosheet stack includes at least one nanosheet; a gate line on the fin-type active region, wherein the gate line extends around the at least one nanosheet, wherein the gate line extends in a second horizontal direction; a gate dielectric film that is in contact with a lower surface and opposite sidewalls of the gate line; a pair of insulating spacers on the opposite sidewalls of the gate line, wherein the pair of insulating spacers are each spaced apart from the gate line in the first horizontal direction with the gate dielectric film therebetween; and a capping insulating pattern that includes a capping lower surface, wherein the capping lower surface is in contact with a gate upper surface of the gate line, an upper surface of the gate dielectric film, and upper surfaces of the pair of insulating spacers, wherein the gate upper surface of the gate line includes a portion that has a decreasing distance from the substrate in the vertical direction as a distance between the portion of the gate upper surface of the gate line and each of the pair of insulating spacers in the first horizontal direction decreases, and wherein the capping insulating pattern includes a center insulating portion that overlaps the gate line in the vertical direction and a pair of side insulating portions that are integrally connected with the center insulating portion and each face the gate line at a distance that is closer than the gate upper surface of the gate line to the substrate.

### BRIEF DESCRIPTION OF THE DRAWINGS

Embodiments of the inventive concept will be more clearly understood from the following detailed description taken in conjunction with the accompanying drawings in which:

FIG. 1 is a block diagram of an integrated circuit device according to some embodiments;

FIG. 2 is a planar layout diagram of some components of an integrated circuit device according to some embodiments;

FIG. 3A is a cross-sectional view illustrating some components of the integrated circuit device of FIG. 2, taken along a line X1-X1′ of FIG. 2;

FIG. 3B is a cross-sectional view illustrating some components of the integrated circuit device of FIG. 2, taken along a line Y1-Y1′ of FIG. 2;

FIG. 3C is a cross-sectional view illustrating some components of the integrated circuit device of FIG. 2, taken along a line X2-X2′ of FIG. 2;

FIG. 4A is an enlarged cross-sectional view of a region EX1 of FIG. 3A;

FIG. 4B is an enlarged cross-sectional view of a region EX2 of FIG. 3C;

FIGS. 5 and 6 are cross-sectional views respectively corresponding to the region EX1 of FIG. 3A according to some embodiments;

FIGS. 7 to 9 are cross-sectional views respectively corresponding to the region EX2 of FIG. 3C according to some embodiments; and

FIGS. 10A to 18H are cross-sectional views illustrating a sequence of processes of a method of fabricating an integrated circuit device, according to some embodiments, and in particular, FIGS. 10A, 11A, 12A, and 13 to 17 are cross-sectional views each illustrating an example of a cross-sectional structure of a portion of the integrated circuit device, which corresponds to the cross-section taken along the line X1-X1′ of FIG. 2, according to the sequence of processes, FIGS. 10B, 11B, and 12B are cross-sectional views each illustrating an example of a cross-sectional structure of a portion of the integrated circuit device, which corresponds to the cross-section taken along the line Y1-Y1′ of FIG. 2, according to the sequence of processes, and FIGS. 18A to 18H are cross-sectional views respectively illustrating sequential processes of the process of FIG. 17 for more detailed descriptions of the process of FIG. 17.

### DETAILED DESCRIPTION

Hereinafter, embodiments of the inventive concept will be described in detail with reference to the accompanying drawings. Like components may be denoted by like reference numerals throughout the specification unless clearly stated otherwise, and repeated descriptions thereof may be omitted.

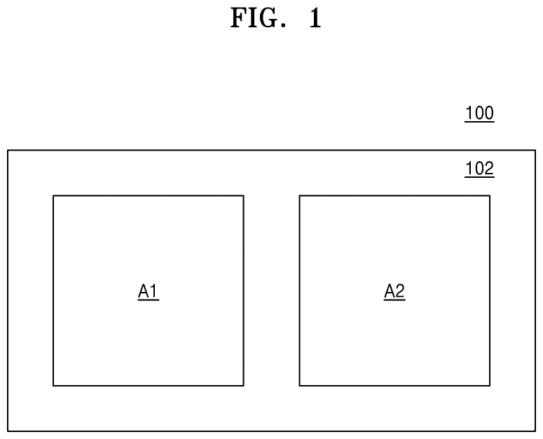

FIG. 1 is a block diagram of an integrated circuit device 100 according to some embodiments.

Referring to FIG. 1, the integrated circuit device 100 may include a substrate 102, which has a first device area A1 and a second device area A2. The first device area A1 and the second device area A2 of the substrate 102 may respectively refer to different areas of the substrate 102 and may respectively be areas performing different operations in the substrate 102. The first device area A1 and the second device area A2 may be apart from each other in the horizontal direction (in a first horizontal direction (e.g., an X direction) and/or a second horizontal direction (e.g., a Y direction)). Hereinafter, the first horizontal direction (e.g., the X direction) is defined as a direction parallel to an upper (and/or a lower) surface of the substrate 102. The second horizontal direction (e.g., the Y direction) is defined as a direction parallel to the upper (and/or the lower) surface of the substrate 102. The first and second horizontal directions intersect each other. A vertical direction (e.g., a Z direction) is defined as a direction perpendicular to the upper (and/or the lower) surface of the substrate 102. As used herein, the term “and/or” includes any and all combinations of one or more of the associated listed items. Expressions such as “at least one of,” when preceding a list of elements, modify the entire list of elements and do not modify the individual elements of the list.

In some embodiments, the first device area A1 may be an area in which devices operating in low-power (lower-power) modes are formed, and the second device area A2 may be an area in which devices operating in high-power (higher-power) modes are formed. For example, the first device area A1 may be an area in which a memory device or a non-memory device is formed, and the second device area A2 may be an area in which a peripheral circuit, such as an input/output (I/O) device, is formed.

In some embodiments, the first device area A1 may be an area constituting a volatile memory device, such as dynamic random access memory (DRAM) or static RAM (SRAM), or a non-volatile memory device, such as read-only memory (ROM), mask ROM (MROM), programmable ROM (PROM), erasable PROM (EPROM), electrically erasable PROM (EEPROM), ferromagnetic RAM (FRAM), phase-change RAM (PRAM), magnetic RAM (MRAM), resistive RAM (RRAM), or flash memory. In some embodiments, the first device area A1 may be an area in which a non-memory device, such as a logic device, is formed. The logic device may include, for example, standard cells, such as a counter and a buffer, which are respectively configured to perform intended logic functions. The standard cells may include various logic cells each including a plurality of circuit elements, such as a transistor, a register, and the like. For example, each of the standard cells may include an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, and/or a combination thereof.

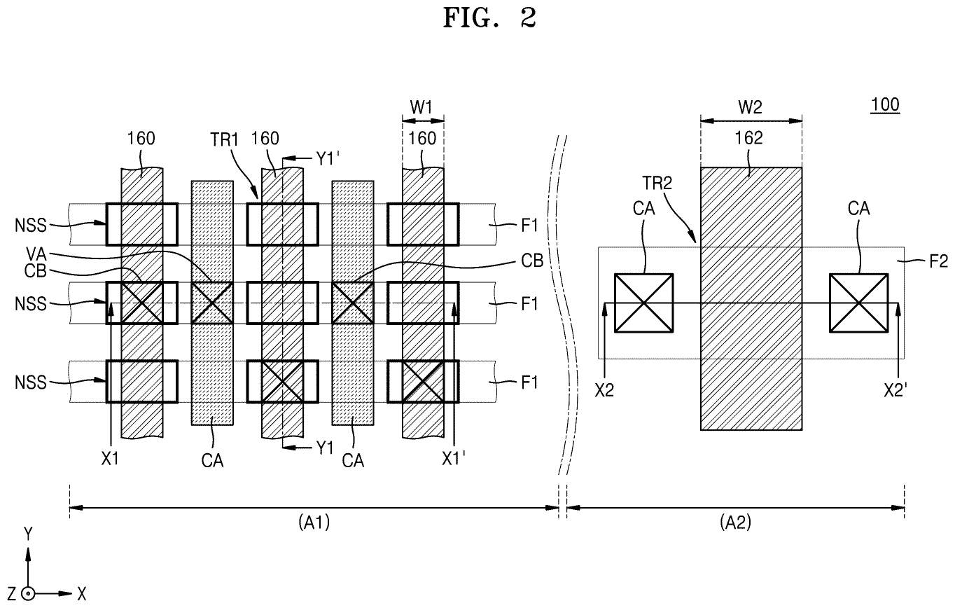

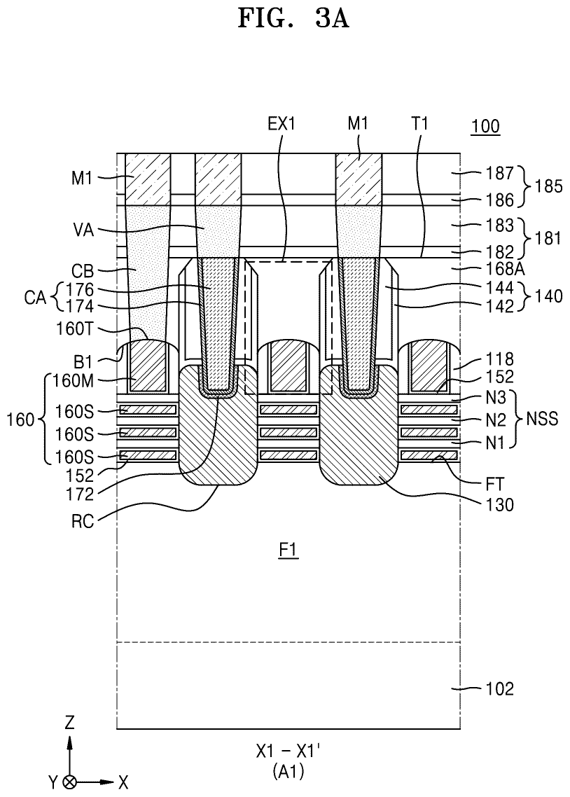

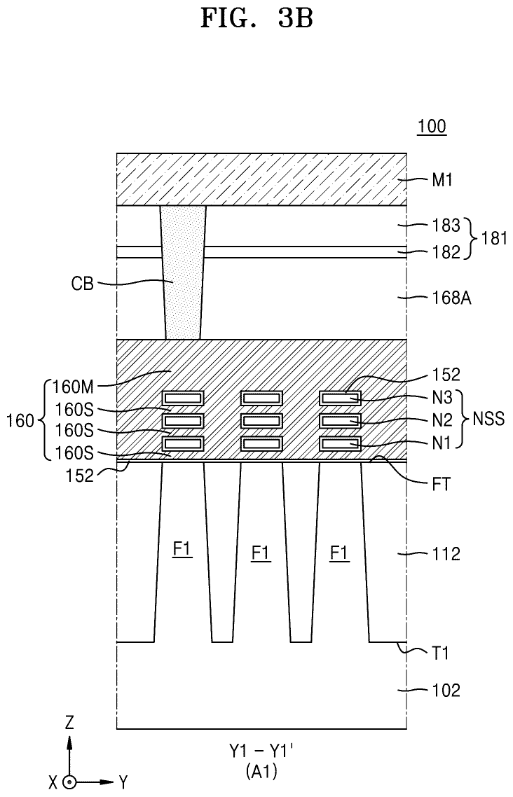

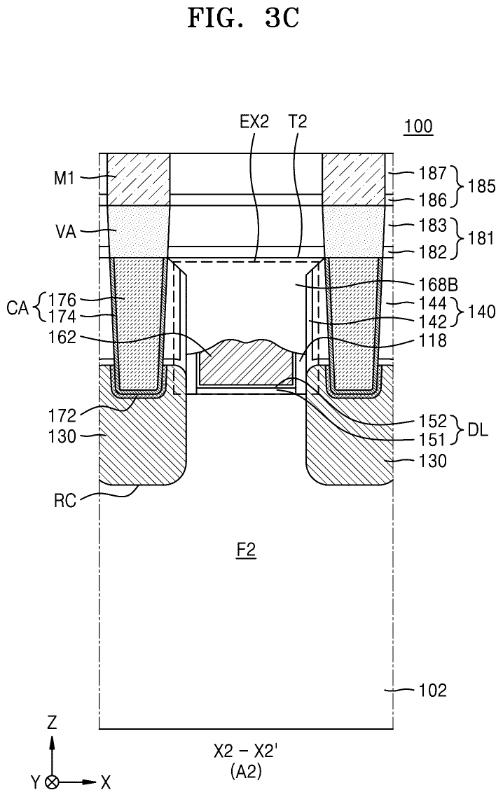

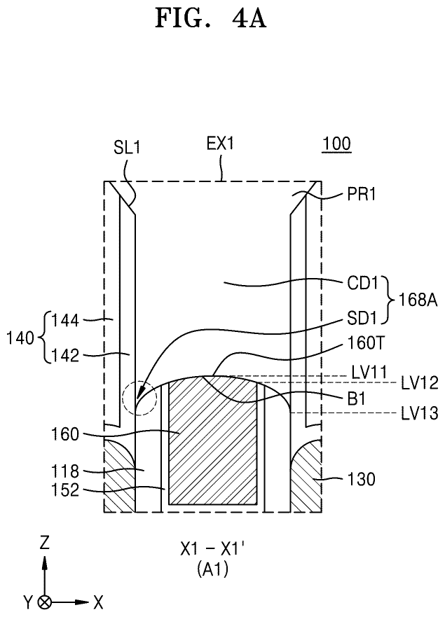

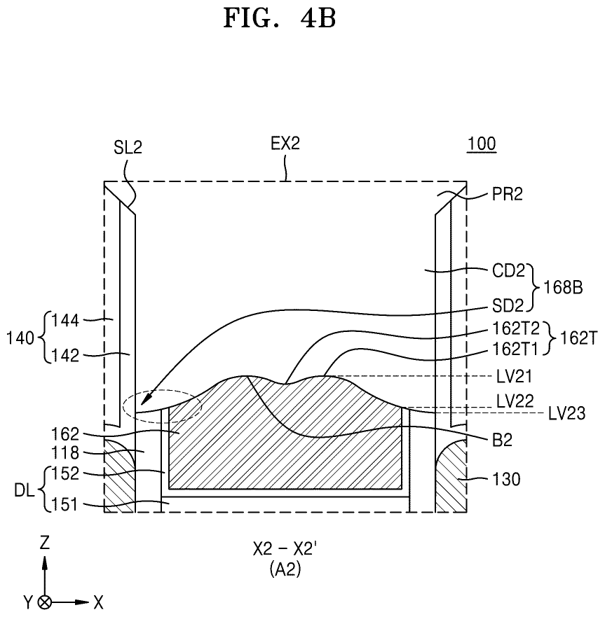

FIG. 2 is a planar layout diagram of some components of the integrated circuit device 100 shown in FIG. 1. FIG. 3A is a cross-sectional view illustrating some components of the integrated circuit device 100, taken along a line X1-X1′ of FIG. 2, FIG. 3B is a cross-sectional view illustrating some components of the integrated circuit device 100, taken along a line Y1-Y1′ of FIG. 2, FIG. 3C is a cross-sectional view illustrating some components of the integrated circuit device 100, taken along a line X2-X2′ of FIG. 2, FIG. 4A is an enlarged cross-sectional view of a region EX1 of FIG. 3A, and FIG. 4B is an enlarged cross-sectional view of a region EX2 of FIG. 3C.

Referring to FIGS. 1, 2, 3A, 3B, 3C, 4A, and 4B, the integrated circuit device 100 may include a plurality of fin-type active regions F1, which each protrude from the substrate 102 in the first device area A1 and each extend lengthwise in the first horizontal direction (e.g., the X direction), and a plurality of nanosheet stacks NSS, which are respectively arranged upwardly apart from the plurality of fin-type active regions F1 in the vertical direction (e.g., the Z direction) to each face a fin upper surface FT of a fin-type active region F1. Herein, the fin-type active region F1 arranged in the first device area A1 may be referred to as a first fin-type active region. As used herein, the term “nanosheet” refers to a conductive structure having a cross-section that is (substantially) perpendicular to a current-flowing direction. The nanosheet may be understood as including a nanowire.

The substrate 102 may include a semiconductor, such as Si and/or Ge, or a compound semiconductor, such as SiGe, SiC, GaAs, InAs, InGaAs, and/or InP. As used herein, each of the terms “SiGe”, “SiC”, “GaAs”, “InAs”, “InGaAs”, and “InP” refers to a material including elements contained in each term and is not a chemical formula representing a stoichiometric relationship. The substrate 102 may include a conductive region, for example, an impurity-doped well or an impurity-doped structure. The substrate 102 may include a device isolation film 112. The device isolation film 112 may include an oxide film, a nitride film, or a combination thereof.

In the first device area A1, a trench T1 may be formed in the substrate 102 to define a plurality of fin-type active regions F1 and may be (at least partially) filled with the device isolation film 112. A plurality of gate lines 160 may be arranged on (over) the plurality of fin-type active regions F1, respectively. Each of the plurality of gate lines 160 may be arranged on (over) the substrate 102 to overlap (e.g., cover) the fin-type active region F1 and may extend lengthwise in the second horizontal direction (e.g., the Y direction). A gate line 160 arranged in the first device area A1 may be referred to as a first gate line. As used herein, “an element A overlapping an element B in a direction X” (or similar language) means that there is at least one line that extends in the direction X and intersects both the elements A and B.

In intersection areas between the plurality of fin-type active regions F1 and the plurality of gate lines 160 in the first device area A1, a plurality of nanosheet stacks NSS may be arranged on (over) a fin upper surface FT of each of the plurality of fin-type active regions F1. Each of the plurality of nanosheet stacks NSS may include at least one nanosheet. As shown in FIGS. 3A and 3B, each of the plurality of nanosheet stacks NSS may include a first nanosheet N1, a second nanosheet N2, and a third nanosheet N3, which overlap each other in the vertical direction (e.g., the Z direction), on (over) the fin-type active region F1. The first nanosheet N1, the second nanosheet N2, and the third nanosheet N3 may respectively have different vertical distances (Z-direction distances) from the fin upper surface FT of the fin-type active region F1. Each of the plurality of gate lines 160 may extend around (e.g., surround) the first nanosheet N1, the second nanosheet N2, and the third nanosheet N3, which are included in the nanosheet stack NSS and overlap each other in the vertical direction (e.g., the Z direction).

Although FIG. 2 illustrates an example in which the planar shape of the nanosheet stack NSS is (approximately) quadrangular, the inventive concept is not limited thereto. The nanosheet stack NSS may have various planar shapes depending on the planar shape of each of the fin-type active region F1 and the gate line 160. The present example illustrates a configuration in which the plurality of nanosheet stacks NSS and the plurality of gate lines 160 are arranged on (over) one fin-type active region F1 and the plurality of nanosheet stacks NSS are arranged (e.g., spaced apart from each other) in the first horizontal direction (e.g., the X direction) on (over) the one fin-type active region F1. However, the respective numbers of the nanosheet stacks NSS and the gate lines 160, which are arranged on (e.g., over) one fin-type active region F1, are not particularly limited.

Each of the first nanosheet N1, the second nanosheet N2, and the third nanosheet N3 of the nanosheet stack NSS may function as a channel region. In some embodiments, each of the first nanosheet N1, the second nanosheet N2, and the third nanosheet N3 may have, but is not limited to, a thickness selected from a range of (about) 4 nm to (about) 6 nm. Here, the thickness of each of the first nanosheet N1, the second nanosheet N2, and the third nanosheet N3 refers to a length in the vertical direction (e.g., the Z direction). In some embodiments, the first nanosheet N1, the second nanosheet N2, and the third nanosheet N3 may have (substantially) the same thickness in the vertical direction (e.g., the Z direction). In some embodiments, at least some of the first nanosheet N1, the second nanosheet N2, and the third nanosheet N3 may have different thicknesses from each other in the vertical direction (e.g., the Z direction).

As shown in FIG. 3A, the first nanosheet N1, the second nanosheet N2, and the third nanosheet N3, which are included in one nanosheet stack NSS, may have equal or similar sizes (e.g., lengths) to each other in the first horizontal direction (e.g., the X direction). In some embodiments, unlike the example shown in FIG. 3A, at least some of the first nanosheet N1, the second nanosheet N2, and the third nanosheet N3, which are included in one nanosheet stack NSS, may have different sizes (e.g., lengths) from each other in the first horizontal direction (e.g., the X direction).

As shown in FIGS. 3A and 3B, each of the plurality of gate lines 160 may include a main gate portion 160M and a plurality of sub-gate portions 160S. The main gate portion 160M may extend lengthwise in the second horizontal direction (e.g., the Y direction) on (e.g., to cover or to overlap) an upper surface of the nanosheet stack NSS. The plurality of sub-gate portions 160S may be integrally connected (e.g., electrically connected) to the main gate portion 160M and may be respectively arranged one-by-one between the first nanosheet N1 and the second nanosheet N2, between the second nanosheet N2 and the third nanosheet N3, and between the first nanosheet N1 and the fin-type active region F1. In the vertical direction (e.g., the Z direction), the thickness of each of the plurality of sub-gate portions 160S may be less than the thickness of the main gate portion 160M. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. Herein, it will be understood that when an element or layer is referred to as being “integrally connected” to another element or layer, those elements are connected to each other without a (visible) boundary therebetween to constitute a greater structure.

As shown in FIG. 3A, a plurality of recesses RC may be formed in the fin-type active region F1. A vertical level of the lower (e.g., the lowermost) surface of each of the plurality of recesses RC may be lower than a vertical level of the fin upper surface FT of the fin-type active region F1. As used herein, the term “vertical level” refers to a distance in the vertical direction (e.g., the Z direction or-Z direction) from a main surface (e.g., an upper surface or a lower surface) of the substrate 102.

As shown in FIG. 3A, a plurality of source/drain regions 130 may be respectively arranged in the plurality of recesses RC. Each of the plurality of source/drain regions 130 may be arranged adjacent to at least one gate line 160 selected from the plurality of gate lines 160. Each of the plurality of source/drain regions 130 may have surfaces respectively facing the first nanosheet N1, the second nanosheet N2, and the third nanosheet N3, which are included in the nanosheet stack NSS adjacent thereto. Each of the plurality of source/drain regions 130 may be in contact with the first nanosheet N1, the second nanosheet N2, and the third nanosheet N3, which are included in the nanosheet stack NSS adjacent thereto.

Each of the plurality of gate lines 160 may include, for example, a metal, a metal nitride, a metal carbide, and/or a combination thereof. The metal may be selected from Mo, Ru, Cu, and W. The metal nitride may be selected from TiN, TaN, TiAlN, and a combination thereof. The metal carbide may include TiAlC. However, a material constituting the plurality of gate lines 160 is not limited to the examples set forth above.

A gate dielectric film 152 may be arranged between the nanosheet stack NSS and the gate line 160. The gate dielectric film 152 may be in contact with the lower surface of the gate line 160 and in contact with both (e.g., opposite) sidewalls of the gate line 160 in the first horizontal direction (e.g., the X direction). The gate dielectric film 152, together with the gate line 160, may extend lengthwise in the second horizontal direction (e.g., the Y direction).

In some embodiments, the gate dielectric film 152 may include a stack structure of an interface dielectric film and a high-K film. The interface dielectric film may include a low-K material film having a dielectric constant of (about) 9 or less, for example, a silicon oxide film, a silicon oxynitride film, and/or a combination thereof. In some embodiments, the interface dielectric film may be omitted. The high-K film may include a material having a dielectric constant that is greater than that of a silicon oxide film. For example, the high-K film may have a dielectric constant of (about) 10 to (about) 25. The high-K film may include, but is not limited to, hafnium oxide.

A plurality of insulating spacers 118 may be arranged on the plurality of fin-type active regions F1 and the device isolation film 112 on the substrate 102 to extend lengthwise in the second horizontal direction (e.g., the Y direction). Herein, an insulating spacer 118 arranged in the first device area A1 may be referred to as a first insulating spacer.

A capping insulating pattern 168 may be on the gate line 160 (e.g., the main gate portion 160M) and the plurality of insulating spacers 118 on the substrate 102. A pair of insulating spacers 118 may be respectively on (e.g., may cover or overlap) both (e.g., opposite) sidewalls of each of the gate line 160 and the capping insulating pattern 168A (e.g., a lower surface of the capping insulating pattern 168A). The insulating spacer 118 may be arranged on the device isolation film 112 and the upper surface of each of the plurality of nanosheet stacks NSS to cover both (e.g., opposite) sidewalls of the main gate portion 160M. The insulating spacer 118 may be apart from the gate line 160 with the gate dielectric film 152 therebetween. The insulating spacer 118 may include, for example, silicon nitride, silicon oxide, SiCN, SiBN, SiON, SiOCN, SiBCN, SiOC, and/or a combination thereof. As used herein, each of the terms “SiCN”, “SiBN”, “SiON”, “SiOCN”, “SiBCN”, and “SiOC” refers to a material including elements contained in each term and is not a chemical formula representing a stoichiometric relationship.

The gate line 160 may extend lengthwise in the second horizontal direction (e.g., the Y direction) in a space, which is defined by the pair of insulating spacers 118, to be on (e.g., cover or overlap) the fin-type active region F1 and the nanosheet stack NSS. For example, the gate line 160 may be between the pair of insulating spacers 118 in the first horizontal direction (e.g., the X direction). The gate dielectric film 152 may be arranged in the space, which is defined by the pair of insulating spacers 118, to contact the surface of each of the first nanosheet N1, the second nanosheet N2, and the third nanosheet N3 of the nanosheet stack NSS and the lower surface and both (e.g., opposite) sidewalls of the gate line 160.

As shown in FIGS. 3A and 3B, the gate upper surface 160T of the gate line 160, the upper surface of the gate dielectric film 152, and the upper surface of each of the pair of insulating spacers 118 respectively covering both (e.g., opposite) sidewalls of the gate line 160 may be covered by the capping insulating pattern 168A. The capping insulating pattern 168A may include a silicon nitride film. The capping insulating pattern 168A in the first device area A1 may be referred to as a first capping insulating pattern.

As shown in FIGS. 3A and 4A, the gate upper surface 160T of the gate line 160, the upper surface of the gate dielectric film 152, and the upper surface of each of the pair of insulating spacers 118 may be in contact with the capping insulating pattern 168A. The gate upper surface 160T of the gate line 160 may have a shape (or a portion) having a decreasing distance (in the vertical direction (e.g., the Z direction)) from the substrate 102 along with the decreasing distance from the gate dielectric film 152 and each of the pair of insulating spacers 118 in the first horizontal direction (e.g., the X direction). For example, the closer a portion of the gate upper surface 160T is to the gate dielectric film 152 and each of the pair of insulating spacers 118 in the first horizontal direction (e.g., the X direction), the closer the portion of the gate upper surface 160T may be to the substrate 102 in the vertical direction (e.g., the Z direction). The gate upper surface 160T of the gate line 160 may have a shape (or a portion) that is convex toward the capping insulating pattern 168A. In some embodiments, (the upper surface of) each of the pair of insulating spacers 118 and (the upper surface of) the gate dielectric film 152 and (the gate upper surface 160T of) the gate line 160, which are between the pair of insulating spacers 118, may constitute a shape (or a portion) that is convex toward the capping insulating pattern 168A.

The capping insulating pattern 168A may have a capping lower surface B1 that is in contact with the gate upper surface 160T of the gate line 160, the upper surface of the gate dielectric film 152, and the upper surface of each of the pair of insulating spacers 118. The capping lower surface B1 of the capping insulating pattern 168A may have a shape (or a portion) having a decreasing distance from the substrate 102 (in the vertical direction (e.g., the Z direction)) along with the decreasing distance from the gate dielectric film 152 and each of the pair of insulating spacers 118 in the first horizontal direction (e.g., the X direction). For example, the closer a portion of the capping lower surface B1 is to the gate dielectric film 152 and each of the pair of insulating spacers 118 in the first horizontal direction (e.g., the X direction), the closer the portion of the capping lower surface B1 may be to the substrate 102 in the vertical direction (e.g., the Z direction). For example, the lower surface B1 of the capping insulating pattern 168A may have a shape (or a portion) that is concave toward an upper surface of the capping insulating pattern 168A.

As shown in FIG. 4A, the capping insulating pattern 168A may include a center insulating portion CD1, which overlaps the gate line 160 in the vertical direction (e.g., the Z direction), and a pair of side insulating portions SD1, which are integrally connected with the center insulating portion CD1. The pair of side insulating portions SD1 may not overlap with the gate line 160 in the vertical direction (e.g., the Z direction). The pair of side insulating portions SD1 may each face the gate line 160 at a vertical level that is closer to the substrate 102 than that of the gate upper surface 160T of the gate line 160. The farthest point of the gate upper surface 160T of the gate line 160 from the substrate 102 (in the vertical direction (e.g., the Z direction)) may be at a first vertical level LV11 above the substrate 102, and the closest point of the gate upper surface 160T of the gate line 160 to the substrate 102 (in the vertical direction (e.g., the Z direction)) may be at a second vertical level LV12 that is closer to the substrate 102 than the first vertical level LV11 (in the vertical direction (e.g., the Z direction)). The lowermost portion, which is closest to the substrate 102 (in the vertical direction (e.g., the Z direction)), in each of the pair of side insulating portions SD1 of the capping insulating pattern 168A may be at a third vertical level LV13 that is closer to the substrate 102 than the second vertical level LV12 (in the vertical direction (e.g., the Z direction)). The respective lowermost portions of the pair of side insulating portions SD1 of the capping insulating pattern 168A may be at the same vertical level above the substrate 102. The pair of side insulating portions SD1 of the capping insulating pattern 168A may respectively have symmetric shapes (or symmetric portions) to each other about the gate line 160.

As shown in FIG. 3A, a (either) sidewall of each of the plurality of sub-gate portions 160S may be apart from the source/drain region 130 with the gate dielectric film 152 therebetween. The gate dielectric film 152 may be (arranged) between a sub-gate portion 160S of the gate line 160 and each of the first nanosheet N1, the second nanosheet N2, and the third nanosheet N3 and between the sub-gate portion 160S of the gate line 160 and the source/drain region 130.

In intersection areas between the plurality of fin-type active regions F1 and the plurality of gate lines 160, the plurality of nanosheet stacks NSS may be arranged on (over) the fin upper surface FT of each of the plurality of fin-type active regions F1 and may be apart from the fin-type active region F1 to face the fin upper surface FT of the fin-type active region F1. A plurality of field-effect transistors TR1, which each have a gate-all-around structure, may be respectively formed on the substrate 102 in the intersection areas between the plurality of fin-type active regions F1 and the plurality of gate lines 160.

Although FIG. 1 illustrates an example in which the planar shape of the nanosheet stack NSS is (approximately) quadrangular, the inventive concept is not limited thereto. The nanosheet stack NSS may have various planar shapes depending on the respective planar shapes of the fin-type active region F1 and the gate line 160. In the present example, it is illustrated that the plurality of nanosheet stacks NSS and the plurality of gate lines 160 are arranged on (over) one fin-type active region F1 and the plurality of nanosheet stacks NSS are arranged in the first horizontal direction (e.g., the X direction) on (over) the one fin-type active region F1. However, according to the inventive concept, the number of nanosheet stacks NSS arranged on (over) one fin-type active region F1 are not particularly limited. For example, one nanosheet stack NSS may be formed on (over) one fin-type active region F1. Although the present example illustrates that each of the plurality of nanosheet stacks NSS includes three nanosheets, the inventive concept is not limited thereto. For example, the nanosheet stack NSS may include at least one nanosheet, and the number of nanosheets constituting the nanosheet stack NSS is not particularly limited.

Each of the first nanosheet N1, the second nanosheet N2, and the third nanosheet N3 of the nanosheet stack NSS may have a channel region. In some embodiments, each of the first nanosheet N1, the second nanosheet N2, and the third nanosheet N3 of the nanosheet stack NSS may include, for example, an Si layer, an SiGe layer, and/or a combination thereof.

A metal silicide film 172 may be formed on the upper surface of each of the plurality of source/drain regions 130. The metal silicide film 172 may include, for example, a metal including Ti, W, Ru, Nb, Mo, Hf, Ni, Co, Pt, Yb, Tb, Dy, Er, and/or Pd. For example, the metal silicide film 172 may include, but is not limited to, titanium silicide.

An insulating liner 142 and an inter-gate dielectric 144 may be sequentially arranged in the stated order on the plurality of source/drain regions 130 and a plurality of metal silicide films 172. The insulating liner 142 and the inter-gate dielectric 144 may constitute an insulating structure 140. The insulating liner 142 may be on (e.g., may cover at least a portion of or overlap) the insulating spacer 118 and the plurality of source/drain regions 130. In some embodiments, the insulating liner 142 may include, but is not limited to, silicon nitride (SiN), SiCN, SiBN, SiON, SiOCN, SiBCN, and/or a combination thereof. The inter-gate dielectric 144 may include, but is not limited to, a silicon oxide film. In some embodiments, the insulating liner 142 may be omitted. When the insulating liner 142 is omitted, the inter-gate dielectric 144 may be in contact with the plurality of source/drain regions 130.

A plurality of source/drain contacts CA may be respectively arranged on the plurality of source/drain regions 130. Each of the plurality of source/drain contacts CA may extend in (e.g., pass through or penetrate) the insulating structure 140, which includes the insulating liner 142 and the inter-gate dielectric 144, in the vertical direction (e.g., the Z direction) to contact the metal silicide film 172. Each of the plurality of source/drain contacts CA may be configured to be electrically connected to the source/drain region 130 via the metal silicide film 172. Each of the plurality of source/drain contacts CA may be apart from the main gate portion 160M in the first horizontal direction (e.g., the X direction) with the insulating spacer 118 therebetween.

Each of the plurality of source/drain contacts CA may include a conductive barrier film 174 and a contact plug 176. The conductive barrier film 174 may be on (e.g., may cover at least a portion of) the lower surface of the contact plug 176 and may be on (e.g., may cover at least a portion of) both (e.g., opposite) sidewalls of the contact plug 176 in the first horizontal direction (e.g., the X direction). The conductive barrier film 174 may be arranged between the metal silicide film 172 and the contact plug 176. The conductive barrier film 174 may be in contact with the metal silicide film 172 and a surface contacting the contact plug 176. In some embodiments, the conductive barrier film 174 may include, for example, a metal or a metal nitride. For example, the conductive barrier film 174 may include, for example, Ti, Ta, W, TiN, TaN, WN, WCN, TiSiN, TaSiN, WSiN, and/or a combination thereof. The contact plug 176 may include, for example, a metal such as molybdenum (Mo), copper (Cu), tungsten (W), cobalt (Co), ruthenium (Ru), manganese (Mn), titanium (Ti), tantalum (Ta), aluminum (Al), and/or a combination thereof.

As shown in FIGS. 3A and 3B, a first upper insulating structure 181 may be on (e.g., may cover at least a portion of or overlap) the respective upper surfaces of the plurality of source/drain contacts CA and a plurality of capping insulating patterns 168A. The first upper insulating structure 181 may include a first etch stop film 182 and a first interlayer dielectric 183, which are sequentially stacked in the stated order on the plurality of capping insulating patterns 168A. The first etch stop film 182 may include, for example, silicon carbide (SiC), SiN, nitrogen-doped silicon carbide (SiC:N), SiOC, AlN, AlON, AlO, AlOC, and/or a combination thereof. The first interlayer dielectric 183 may include, for example, an oxide film, a nitride film, an ultra-low-K film having an ultra-low dielectric constant (that is, K) of (about) 2.2 to (about) 2.4, and/or a combination thereof. For example, the first interlayer dielectric 183 may include, but is not limited to, a tetraethyl orthosilicate (TEOS) film, a high-density plasma (HDP) oxide film, a boro-phospho-silicate glass (BPSG) film, a flowable chemical vapor deposition (FCVD) oxide film, an SiON film, an SiN film, an SiOC film, an SiCOH film, and/or a combination thereof.

A gate contact CB may be arranged on the gate line 160, the gate contact CB being connected (e.g., electrically connected) to the gate line 160. The gate contact CB may extend in (e.g., pass through or penetrate) the first upper insulating structure 181 and each of the plurality of capping insulating patterns 168A in the vertical direction (e.g., the Z direction) on the gate line 160. The lower surface of the gate contact CB may be in contact with the gate upper surface (e.g., the uppermost surface) 160T of the gate line 160. The gate upper surface 160T of the gate line 160 may have a shape (or a portion) that is convex toward the gate contact CB, and the capping lower surface B1 of the gate contact CB may have a shape (or a portion) that is concave toward the upper surface of the gate contact CB. In some embodiments, the gate contact CB may include, but is not limited to, a metal film including a single metal selected from Mo, Ru, Cu, and W.

A plurality of via contacts VA may be respectively arranged on the plurality of source/drain contacts CA. The upper surface of each of the plurality of via contacts VA and the upper surface of each of a plurality of gate contacts CB may be at the same vertical level on (above) the substrate 102. In some embodiments, each of the plurality of via contacts VA may include, but is not limited to, a metal film selected from Mo, Ru, Cu, and W.

As shown in FIGS. 3A and 3B, a second upper insulating structure 185 may be on (e.g., may cover at least a portion of or overlap) the first upper insulating structure 181. The second upper insulating structure 185 may include a second etch stop film 186 and a second interlayer dielectric 187, which are sequentially stacked in the stated order on the first upper insulating structure 181. More detailed configurations of the second etch stop film 186 and the second interlayer dielectric 187 are respectively the same as those of the first etch stop film 182 and the first interlayer dielectric 183, which are described above.

A plurality of upper wiring layers M1 may be arranged in the second upper insulating structure 185. The plurality of upper wiring layers M1 may include an upper wiring layer M1 connected (e.g., electrically connected) to the via contact VA and an upper wiring layer M1 connected (e.g., electrically connected) to the gate contact CB. Each of the plurality of upper wiring layers M1 may include, but is not limited to, Mo, Cu, W, Co, Ru, Mn, Ti, Ta, Al, a combination thereof, and/or an alloy thereof.

As shown in FIGS. 2, 3C, and 4B, the integrated circuit device 100 may include a fin-type active region F2, which protrudes from the substrate 102 and extends lengthwise in the first horizontal direction (X direction), in the second device area A2. The fin-type active region F2 may have (substantially) the same configuration as that of the fin-type active region F1 described above. Herein, the fin-type active region F2 arranged in the second device area A2 may be referred to as a second fin-type active region.

A channel region in the fin-type active region F2 may be defined by a plurality of recesses RC formed in the fin-type active region F2. For example, the channel region may be between the adjacent recesses RC among the plurality of recesses RC. A plurality of source/drain regions 130 may be respectively formed in (on) the plurality of recesses RC in the fin-type active region F2.

In the second device area A2, a gate line 162 may be on (e.g., arranged over) the fin-type active region F2. In the second device area A2, a field-effect transistor TR2 may be formed in an intersection area between the fin-type active region F2 and the gate line 162. Herein, the gate line 162 in the second device area A2 may be referred to as a second gate line. The gate line 160 in the first device area A1 may have a first width W1 in the first horizontal direction (e.g., the X direction), and the gate line 162 in the second device area A2 may have a second width W2, which is greater than the first width W1 of the gate line 160, in the first horizontal direction (e.g., the X direction).

The gate line 162 may include, for example, a metal, a metal nitride, a metal carbide, and/or a combination thereof. The metal may include, for example, Mo, Ru, Cu, and/or W. The metal nitride may include, for example, TiN, TaN, TiAlN, and/or a combination thereof. The metal carbide may include, for example, TiAlC. However, a material constituting the gate line 162 is not limited to the examples set forth above. In some embodiments, the gate line 160 in the first device area A1 and the gate line 162 in the second device area A2 may have the same stack structure. In some embodiments, the gate line 160 in the first device area A1 and the gate line 162 in the second device area A2 may have different structures from each other.

As shown in FIG. 3C, a multi-gate dielectric film DL may be (arranged) between the fin-type active region F2 and the gate line 162. The multi-gate dielectric film DL may be in contact with the lower surface of the gate line 162 and in contact with both (e.g., opposite) sidewalls of the gate line 162 in the first horizontal direction (X direction). The multi-gate dielectric film DL may include an interface dielectric film 151, which is on (e.g., covers at least a portion of, overlaps, or contacts) the fin-type active region F2, and a gate dielectric film 152, which is apart from the fin-type active region F2 with the interface dielectric film 151 therebetween and contacts the gate line 162. In some embodiments, the interface dielectric film 151 may include a low-K material film having a dielectric constant of (about) 9 or less, for example, a silicon oxide film, a silicon oxynitride film, and/or a combination thereof. A detailed configuration of the gate dielectric film 152 in the second device area A2 may be the same as that of the gate dielectric film 152 in the first device area A1, which has been described with reference to FIGS. 3A, 3B, and 4A.

A pair of insulating spacers 118 may be (arranged) on the fin-type active region F2 to be respectively on (e.g., cover at least a portion of or overlap) both (e.g., opposite) sidewalls of the gate line 162 and may extend lengthwise in the second horizontal direction (e.g., the Y direction). Herein, the insulating spacer 118 (arranged) in the second device area A2 may be referred to as a second insulating spacer. In the second device area A2, the insulating spacer 118 may be apart from the gate line 162 (in the first horizontal direction) with the gate dielectric film 152 therebetween. The gate line 162 may extend lengthwise in the second horizontal direction (e.g., the Y direction) in a space, which is defined by the pair of insulating spacers 118, on (e.g., may cover at least a portion of or overlap) the fin-type active region F2. For example, the gate line 162 may be between the (adjacent) insulating spacers 118 in the first horizontal direction (e.g., the X direction).

As shown in FIGS. 3C and 4B, a capping insulating pattern 168B may be on (e.g., may cover at least a portion of or overlap) a gate upper surface 162T of the gate line 162, the upper surface of the gate dielectric film 152, and the upper surface of each of the pair of insulating spacers 118 respectively on (e.g., covering at least a portion of or overlapping) both (e.g., opposite) sidewalls of the gate line 162. The capping insulating pattern 168B may include, for example, a silicon nitride film. The capping insulating pattern 168B in the second device area A2 may be referred to as a second capping insulating pattern.

The gate upper surface 162T of the gate line 162, the upper surface of the gate dielectric film 152, and the upper surface of each of the pair of insulating spacers 118 may be in contact with the capping insulating pattern 168B. The gate upper surface 162T of the gate line 162 may have a shape (or a portion) having a decreasing distance from the substrate 102 along with the decreasing distance from the gate dielectric film 152 and each of the pair of insulating spacers 118 in the first horizontal direction (e.g., the X direction). The gate upper surface 162T of the gate line 162 may have a shape (or a portion) that is (generally) convex toward the capping insulating pattern 168B. For example, the closer a first portion of the gate upper surface 162T is to the gate dielectric film 152 and each of the pair of insulating spacers 118 in the first horizontal direction (e.g., the X direction), the closer the first portion of the gate upper surface 162T may be to the substrate 102 in the vertical direction (e.g., the Z direction). For example, the closer a second portion of the gate upper surface 162T is to the gate dielectric film 152 and each of the pair of insulating spacers 118 in the first horizontal direction (e.g., the X direction), the farther the second portion of the gate upper surface 162T may be to the substrate 102 in the vertical direction (e.g., the Z direction).

The capping insulating pattern 168B may have a capping lower surface B2 that is in contact with the gate upper surface 162T of the gate line 162, the upper surface of the gate dielectric film 152, and the upper surface of each of the pair of insulating spacers 118. The capping lower surface B2 of the capping insulating pattern 168B may have a shape (or a portion) having a decreasing distance from the substrate 102 along with the decreasing distance from the gate dielectric film 152 and each of the pair of insulating spacers 118 in the first horizontal direction (e.g., the X direction). For example, the capping lower surface B2 of the capping insulating pattern 168B may be (generally) concave toward the upper surface of the capping insulating pattern 168B. For example, the closer a first portion of the capping lower surface B2 is to the gate dielectric film 152 and each of the pair of insulating spacers 118 in the first horizontal direction (e.g., the X direction), the closer the first portion of the capping lower surface B2 may be to the substrate 102 in the vertical direction (e.g., the Z direction). For example, the closer a second portion of the capping lower surface B2 is to the gate dielectric film 152 and each of the pair of insulating spacers 118 in the first horizontal direction (e.g., the X direction), the farther the second portion of the capping lower surface B2 may be to the substrate 102 in the vertical direction (e.g., the Z direction).

As shown in FIG. 4B, the capping insulating pattern 168B may include a center insulating portion CD2, which overlaps the gate line 162 in the vertical direction (e.g., the Z direction), and a pair of side insulating portions SD2, which are integrally connected with the center insulating portion CD2. The pair of side insulating portions SD2 may each face the gate line 162 at a vertical level that is closer to the substrate 102 than that of the gate upper surface 162T of the gate line 162. For example, the side insulating portions SD2 may not overlap the gate line 162 in the vertical direction (e.g., the Z direction). The farthest point 162T1 of the gate upper surface 162T of the gate line 162 from the substrate 102 may be at a first vertical level LV21 on (above) the substrate 102, and the closest point of the gate upper surface 162T of the gate line 162 to the substrate 102 may be at a second vertical level LV22 that is closer to the substrate 102 than the first vertical level LV21. The lowermost portion, which is closest to the substrate 102, in each of the pair of side insulating portions SD2 of the capping insulating pattern 168B may be at a third vertical level LV23 that is closer to the substrate 102 than the second vertical level LV22. The respective lowermost portions of the pair of side insulating portions SD2 of the capping insulating pattern 168B may be at the same vertical level on (above) the substrate 102. The pair of side insulating portions SD2 of the capping insulating pattern 168B may respectively have symmetric shapes (or symmetric portions) to each other about the gate line 162.

As shown in FIGS. 3C and 4B, the vertical level of a center point 162T2 of the gate upper surface 162T of the gate line 162 based on the first horizontal direction (e.g., the X direction) may be closer to the substrate 102 than the first vertical level LV21 of the farthest point 162T1 of the gate upper surface 162T of the gate line 162 from the substrate 102 and be farther from the substrate 102 than the second vertical level LV22 of the closest point of the gate upper surface 162T of the gate line 162 to the substrate 102. Therefore, the uppermost portion, which is farthest from the substrate 102, in the gate upper surface 162T of the gate line 162 may be at a position biased to one side in the first horizontal direction (X direction) from the center point 162T2 of the gate upper surface 162T of the gate line 162 based on the first horizontal direction (e.g., the X direction). For example, the center point 162T2 may be between the adjacent farthest points 162T1 in the first horizontal direction (e.g., the X direction). In some embodiments, a distance between the gate upper surface 162T and the substrate 102 in the vertical direction (e.g., the Z direction) may increase between one side of the gate dielectric film 152 and one of the adjacent farthest points 162T1. The distance between the gate upper surface 162T and the substrate 102 in the vertical direction (e.g., the Z direction) may decrease between the one of the adjacent farthest points 162T1 and the center point 162T2. The distance between the gate upper surface 162T and the substrate 102 in the vertical direction (e.g., the Z direction) may increase between the center point 162T2 and the other of the adjacent farthest points 162T1. The distance between the gate upper surface 162T and the substrate 102 in the vertical direction (e.g., the Z direction) may decrease between the other of the adjacent farthest points 162T1 and the other side of the gate dielectric film 152.

In the second device area A2, the metal silicide film 172 may be formed on the upper surface of each of the plurality of source/drain regions 130. The insulating liner 142 and the inter-gate dielectric 144 may be sequentially arranged in the stated order on the plurality of source/drain regions 130 and the plurality of metal silicide films 172. The plurality of source/drain contacts CA, which are respectively arranged on the plurality of source/drain regions 130, may each extend in (e.g., pass through or penetrate) the insulating structure 140, which includes the insulating liner 142 and the inter-gate dielectric 144, in the vertical direction (e.g., the Z direction) to contact the metal silicide film 172. Each of the plurality of source/drain contacts CA may be configured to be electrically connected to the source/drain region 130 via the metal silicide film 172. In the second device area A2, each of the plurality of source/drain contacts CA may be apart from the gate line 162 in the first horizontal direction (e.g., the X direction) with the insulating spacer 118 therebetween. More detailed configurations of the plurality of source/drain contacts CA may be the same as described above with reference to FIG. 3A.

In the second device area A2, similar to the descriptions made with reference to FIGS. 3A and 3B, the first upper insulating structure 181, the plurality of via contacts VA, the second upper insulating structure 185, and the plurality of upper wiring layers M1 may be arranged on or over the plurality of source/drain contacts CA and the plurality of capping insulating patterns 168B.

As shown in FIGS. 3A and 4A, in the first device area A1, a portion of the gate line 160 may face the source/drain contact CA in the first horizontal direction (e.g., the X direction), and the side insulating portion SD1 of the capping insulating pattern 168A may be arranged between the gate line 160 and the source/drain contact CA in the first horizontal direction (e.g., the X direction).

As shown in FIGS. 3C and 4B, in the second device area A2, a portion of the gate line 162 may face the source/drain contact CA in the first horizontal direction (e.g., the X direction), and the side insulating portion SD2 of the capping insulating pattern 168B may be arranged between the gate line 162 and the source/drain contact CA in the first horizontal direction (e.g., the X direction).

As shown in FIGS. 3A, 3C, 4A, and 4B, in the first device area A1 and the second device area A2, the capping insulating patterns 168A and 168B may have capping upper surfaces T1 and T2, which are opposite to the capping lower surfaces B1 and B2, respectively. The capping insulating patterns 168A and 168B may include protrusions PR1 and PR2, which are located adjacent to the capping upper surfaces T1 and T2 thereof to protrude outwards in the first horizontal direction (e.g., the X direction), respectively. In some embodiments, the protrusions PR1 and PR2 may be parts of the capping insulating patterns 168A and 168, respectively. For example, the capping upper surfaces T1 and T2 may include upper surfaces of the protrusions PR1 and PR2, respectively. In some embodiments, the protrusions PR1 and PR2 may not overlap the capping lower surfaces B1 and B2 in the vertical direction (e.g., the Z direction), respectively. The insulating structure 140, which includes the insulating liner 142 and the inter-gate dielectric 144, may have inclined surfaces SL1 and SL2 that are respectively in contact with the protrusions PR1 and PR2. Surfaces of the protrusions PR1 and PR2, which are respectively in contact with the inclined surfaces SL1 and SL2 of the insulating structures 140, may include inclined surfaces corresponding to the inclined surfaces SL1 and SL2, respectively.

According to the integrated circuit device 100 described with reference to FIGS. 1 to 4B, each of the gate upper surfaces 160T and 162T of the gate lines 160 and 162 respectively in the first device area A1 and the second device area A2 has a shape (or a portion) that is (generally) convex upwards to have a decreasing distance from the substrate 102 along with the decreasing distance from the gate dielectric film 152 in the first horizontal direction (e.g., the X direction), and the capping insulating patterns 168A and 168B, which respectively cover (at least a portion of) the gate upper surfaces 160T and 162T of the gate lines 160 and 162, respectively include pairs of side insulating portions SD1 and SD2, which respectively face the gate lines 160 and 162 at vertical levels closer to the substrate 102 than those of the gate upper surfaces 160T and 162T of the gate lines 160 and 162. Because each of the side insulating portions SD1 and SD2 is arranged between the gate line 160 or 162 and the source/drain contact CA adjacent thereto, (unintended or defective) parasitic capacitance between the gate line 160 or 162 and the source/drain contact CA may be reduced and the possibility of (unintended or defective) short-circuits between the gate line 160 or 162 and the source/drain contact CA may be removed. Therefore, in the integrated circuit device 100 having a reduced device area due to down-scaling, the reliability of the integrated circuit device 100 may improve.

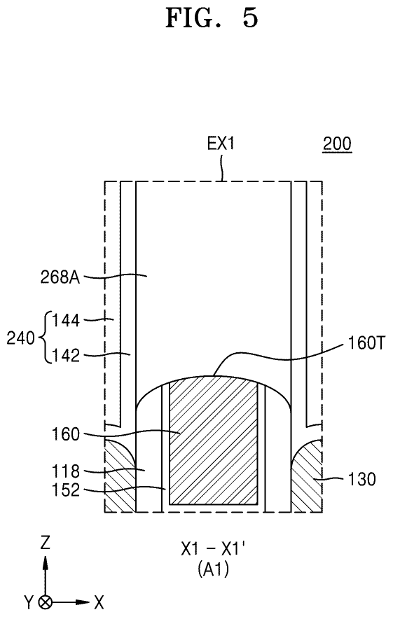

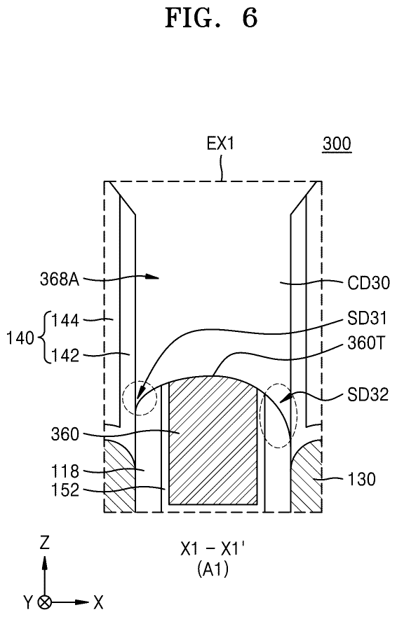

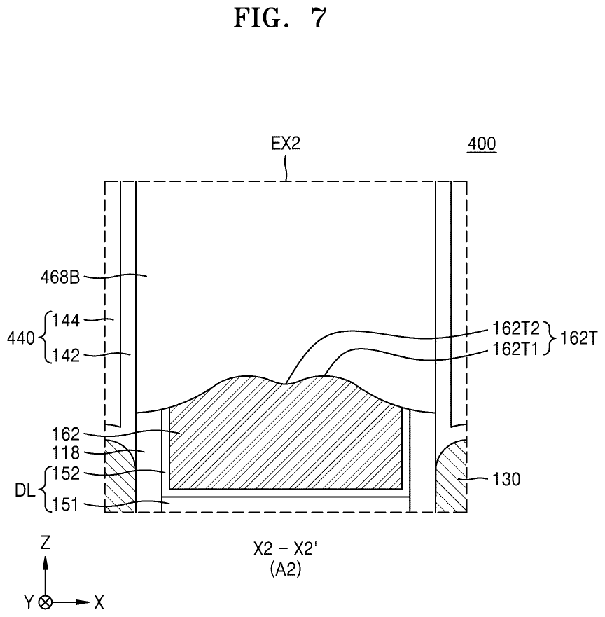

FIGS. 5 to 9 are cross-sectional views respectively illustrating integrated circuit devices 200, 300, 400, 500, and 600 according to some embodiments. FIGS. 5 and 6 each illustrate an enlarged cross-sectional configuration of a region corresponding to the region EX1 of FIG. 3A. FIGS. 7, 8, and 9 each illustrate an enlarged cross-sectional configuration of a region corresponding to the region EX2 of FIG. 3C. In FIGS. 5 to 9, the same reference numerals as in FIGS. 1 to 4B respectively denote the same members unless clearly stated otherwise, and here, repeated descriptions thereof may be omitted.

Referring to FIG. 5, the integrated circuit device 200 may have (substantially) the same configuration as the integrated circuit device 100 described with reference to FIGS. 1 to 4B. However, the integrated circuit device 200 may include a capping insulating pattern 268A, instead of the capping insulating pattern 168A, in the first device area A1. Both (e.g., opposite) sidewalls of the capping insulating pattern 268A in the first horizontal direction (e.g., the X direction) may extend flat (in the second horizontal direction (e.g., the Y direction) and/or the vertical direction (e.g., the Z direction)) without any protrusion that protrudes outwards (in the first horizontal direction (e.g., the X direction)).

The integrated circuit device 200 may include an insulating structure 240, which is on (e.g., covers at least a portion of or overlaps) both (e.g., opposite) sidewalls of the capping insulating pattern 268A in the first horizontal direction (e.g., the X direction). The insulating structure 240 may include an insulating liner 142 and an inter-gate dielectric 144. The insulating structure 240 may have (substantially) the same configuration as the insulating structure 140 described with reference to FIGS. 3A, 3C, 4A, and 4B. However, the insulating structure 240 does not include the inclined surface SL1 shown in FIG. 4A. An interface between the insulating structure 240 and both (e.g., opposite) sidewalls of the capping insulating pattern 268A may extend (substantially) flat (in the second horizontal direction (e.g., the Y direction) and/or the vertical direction (e.g., the Z direction)) without any curved surface, such as an inclined surface.

Referring to FIG. 6, the integrated circuit device 300 may have (substantially) the same configuration as the integrated circuit device 100 described with reference to FIGS. 1 to 4B. However, the integrated circuit device 300 may include a gate line 360 and a capping insulating pattern 368A, instead of the gate line 160 and the capping insulating pattern 168A, in the first device area A1.

The gate line 360 may have (substantially) the same configuration as the gate line 160 described with reference to FIGS. 2, 3A, 3B, and 4A. However, a gate upper surface 360T of the gate line 360 may have an asymmetric shape (or an asymmetric portion) about a line that passes through, in the vertical direction (e.g., the Z direction), the center of the gate line 360 based on the first horizontal direction (e.g., the X direction).

The capping insulating pattern 368A may include a center insulating portion CD30, which overlaps the gate line 360 in the vertical direction (e.g., the Z direction), and a pair of side insulating portions SD31 and SD32, which are integrally connected with the center insulating portion CD30. The pair of side insulating portions SD31 and SD32 may each face the gate line 360 at a vertical level that is closer to the substrate 102 than that of the gate upper surface 360T of the gate line 360. More detailed configurations of the capping insulating pattern 368A may be (substantially) the same as those of the capping insulating pattern 168A described with reference to FIGS. 3A and 4A. However, the respective lowermost portions of the pair of side insulating portions SD31 and SD32 of the capping insulating pattern 368A are at different vertical levels on (e.g., above) the substrate 102. The pair of side insulating portions SD31 and SD32 respectively have different shapes (e.g., asymmetric shapes (or asymmetric portions) to each other about the gate line 360).

Referring to FIG. 7, the integrated circuit device 400 may have (substantially) the same configuration as the integrated circuit device 100 described with reference to FIGS. 1 to 4B. However, the integrated circuit device 400 may include a capping insulating pattern 468B, instead of the capping insulating pattern 168B, in the second device area A2. Both (opposite) sidewalls of the capping insulating pattern 468B in the first horizontal direction (e.g., the X direction) may extend flat (in the second horizontal direction (e.g., the Y direction) and/or the vertical direction (e.g., the Z direction)) without any protrusion that protrudes outwards (in the first horizontal direction (e.g., the X direction)).

The integrated circuit device 400 may include an insulating structure 440, which is on (e.g., covers at least a portion of or overlaps) both (e.g., opposite) sidewalls of the capping insulating pattern 468B in the first horizontal direction (e.g., the X direction). The insulating structure 440 may include an insulating liner 142 and an inter-gate dielectric 144. The insulating structure 440 may have (substantially) the same configuration as the insulating structure 140 described with reference to FIGS. 3A, 3C, 4A, and 4B. However, the insulating structure 440 may not include the inclined surface SL2 shown in FIG. 4B. An interface between the insulating structure 440 and both (e.g., opposite) sidewalls of the capping insulating pattern 468B may extend (substantially) flat (in the second horizontal direction (e.g., the Y direction) and/or the vertical direction (e.g., the Z direction)) without any curved surface, such as an inclined surface.

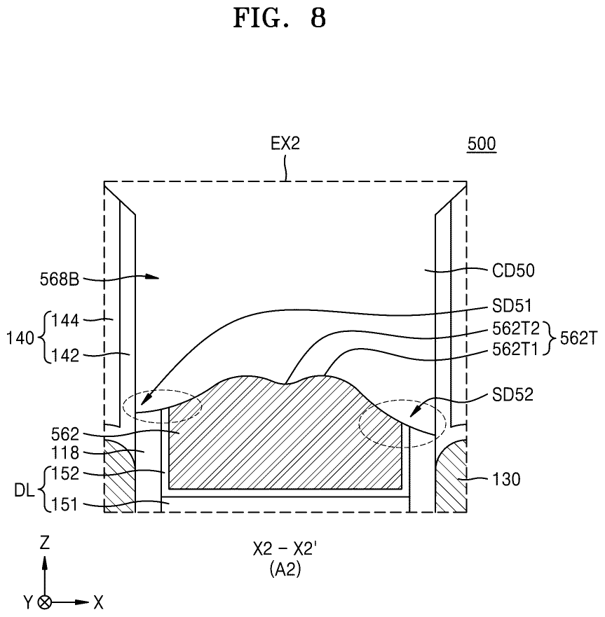

Referring to FIG. 8, the integrated circuit device 500 may have (substantially) the same configuration as the integrated circuit device 100 described with reference to FIGS. 1 to 4B. However, the integrated circuit device 500 may include a gate line 562 and a capping insulating pattern 568B, instead of the gate line 162 and the capping insulating pattern 168B, in the second device area A2.

The gate line 562 may have (substantially) the same configuration as the gate line 162 described with reference to FIGS. 2, 3C, and 4B. However, a gate upper surface 562T of the gate line 562 may have an asymmetric shape (or an asymmetric portion) about a line that passes through, in the vertical direction (e.g., the Z direction), the center of the gate line 562 based on the first horizontal direction (e.g., the X direction).

The capping insulating pattern 568B may include a center insulating portion CD50, which overlaps the gate line 562 in the vertical direction (e.g., the Z direction), and a pair of side insulating portions SD51 and SD52, which are integrally connected with the center insulating portion CD50. The pair of side insulating portions SD51 and SD52 may not overlap the gate line 562 in the vertical direction (e.g., the Z direction). The pair of side insulating portions SD51 and SD52 may each face the gate line 562 at a vertical level that is closer to the substrate 102 than that of the gate upper surface 562T of the gate line 562. More detailed configurations of the capping insulating pattern 568B may be (substantially) the same as those of the capping insulating pattern 168B described with reference to FIGS. 3C and 4B. However, the respective lowermost portions of the pair of side insulating portions SD51 and SD52 of the capping insulating pattern 568B are at different vertical levels on (above) the substrate 102. The pair of side insulating portions SD51 and SD52 respectively have different shapes (asymmetric shapes (or asymmetric portions) to each other about the gate line 562).

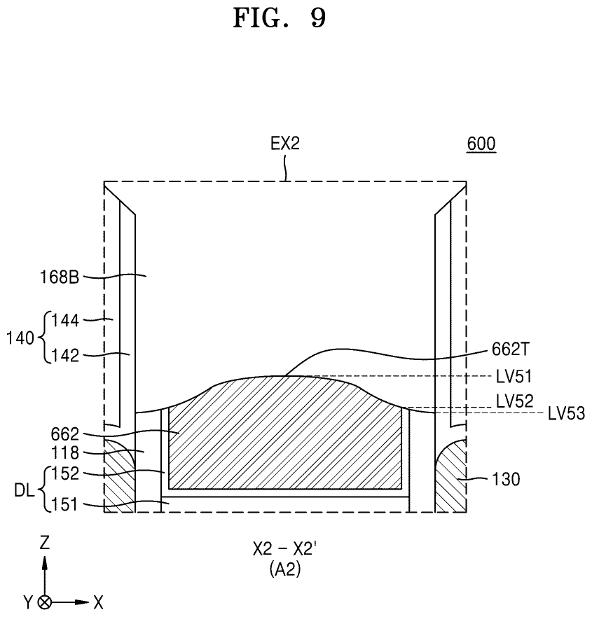

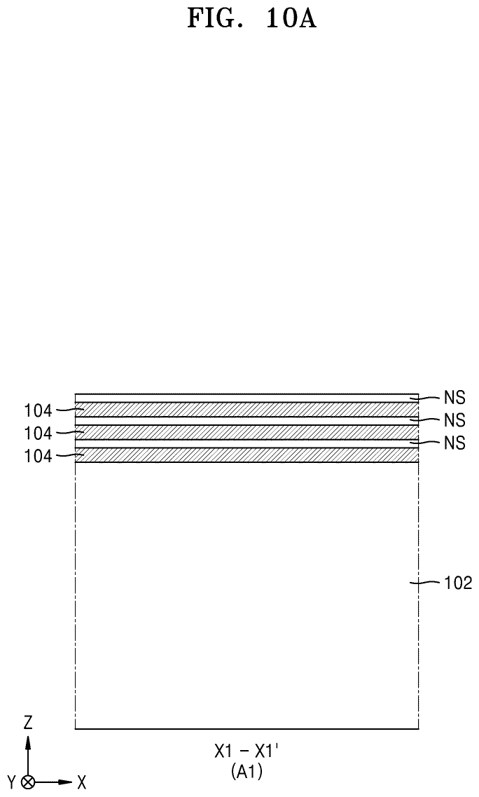

Referring to FIG. 9, the integrated circuit device 600 may have (substantially) the same configuration as the integrated circuit device 100 described with reference to FIGS. 1 to 4B. However, the integrated circuit device 600 may include a gate line 662, instead of the gate line 162, in the second device area A2.

The gate line 662 may have (substantially) the same configuration as the gate line 162 described with reference to FIGS. 2, 3C, and 4B. However, the uppermost portion, which is farthest from the substrate 102, in a gate upper surface 662T of the gate line 662 may be at the center portion (e.g., center point) in the gate upper surface 662T of the gate line 662 in terms of the first horizontal direction (e.g., the X direction).

According to the integrated circuit devices 200, 300, 400, 500, and 600 described with reference to FIGS. 5 to 9, similar to the integrated circuit device 100 described with reference to FIGS. 1 to 4B, each of the gate upper surfaces 160T, 162T, 360T, 562T, and 662T of the gate lines 160, 162, 360, 562, and 662 may have a shape (or a portion) that is (generally) convex upwards to have a decreasing distance from the substrate 102 along with the decreasing distance from the gate dielectric film 152 in the first horizontal direction (e.g., the X direction), and the capping insulating pattern 168B, 268A, 368A, 468B, or 568B, which is on (e.g., covers at least a portion of or overlaps) the gate upper surface 160T, 162T, 360T, 562T, or 662T of the gate line 160, 162, 360, 562, or 662, may include the side insulating portion SD1, SD2, SD31, SD32, SD51, or SD52, which faces the gate line 160, 162, 360, 562, or 662 at a vertical level that is closer to the substrate 102 than that of the gate upper surface 160T, 162T, 360T, 562T, or 662T of the gate line 160, 162, 360, 562, or 662. Because each of the side insulating portions SD1, SD2, SD31, SD32, SD51, and SD52 is arranged between the gate line 160, 162, 360, 562, or 662 and the source/drain contact CA adjacent to the gate line 160, 162, 360, 562, or 662, (unintended or defective) parasitic capacitance between the gate line 160, 162, 360, 562, or 662 and the source/drain contact CA may be reduced and the possibility of (unintended or defective) short-circuit between the gate line 160, 162, 360, 562, or 662 and the source/drain contact CA may be removed. Therefore, in each of the integrated circuit devices 200, 300, 400, 500, and 600 having reduced device areas due to down-scaling, the reliability of each of the integrated circuit devices 200, 300, 400, 500, and 600 may improve.

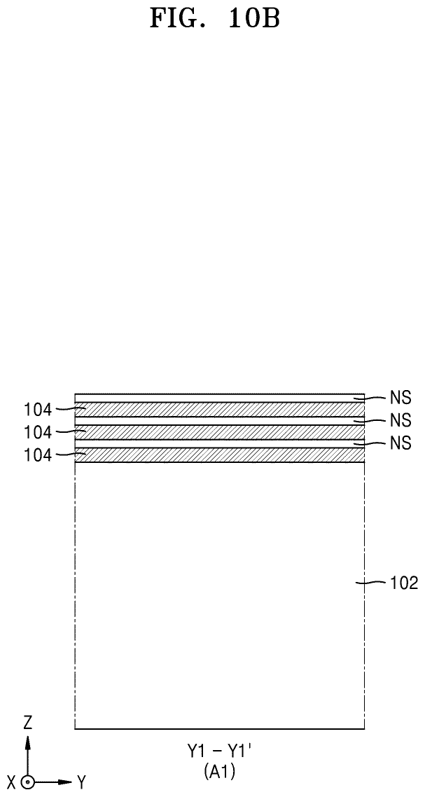

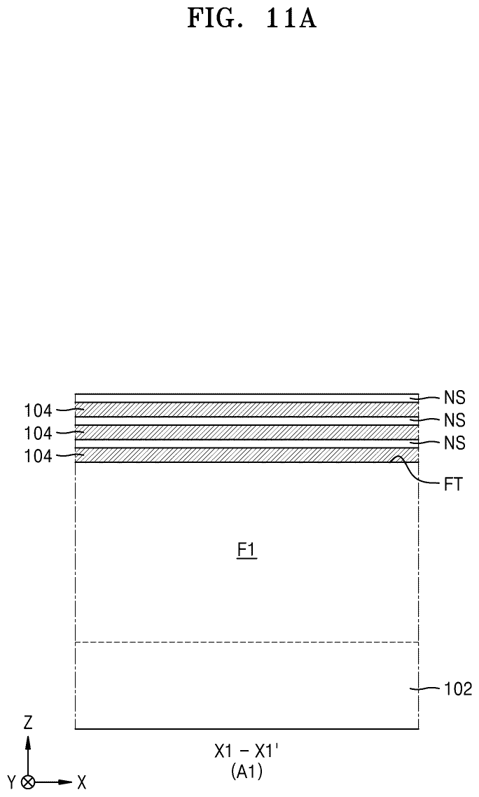

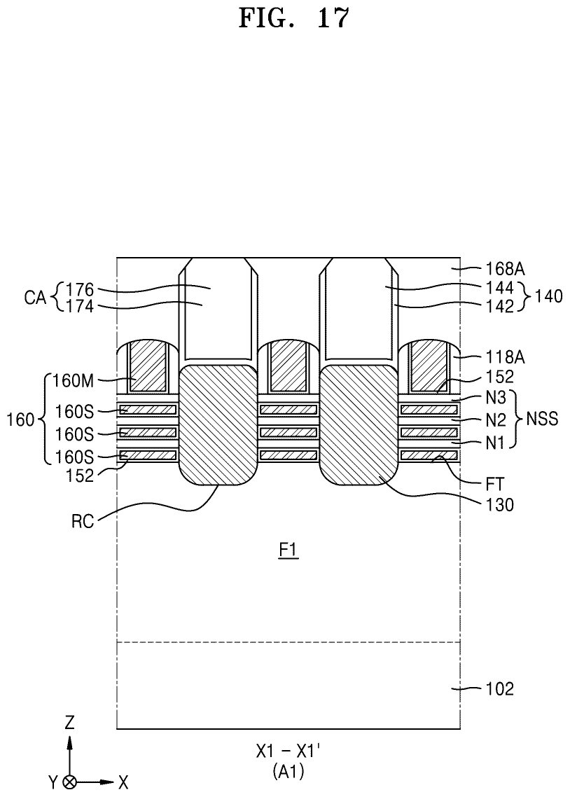

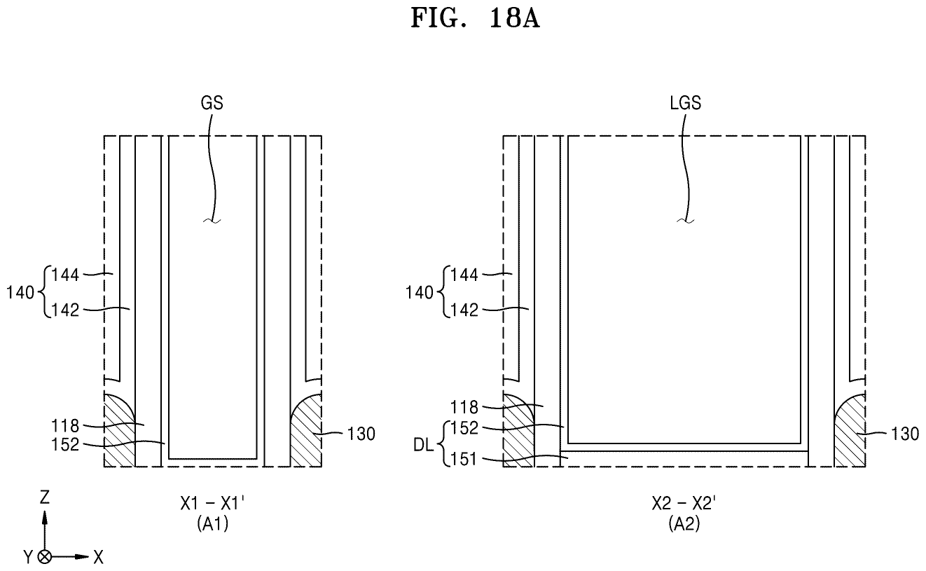

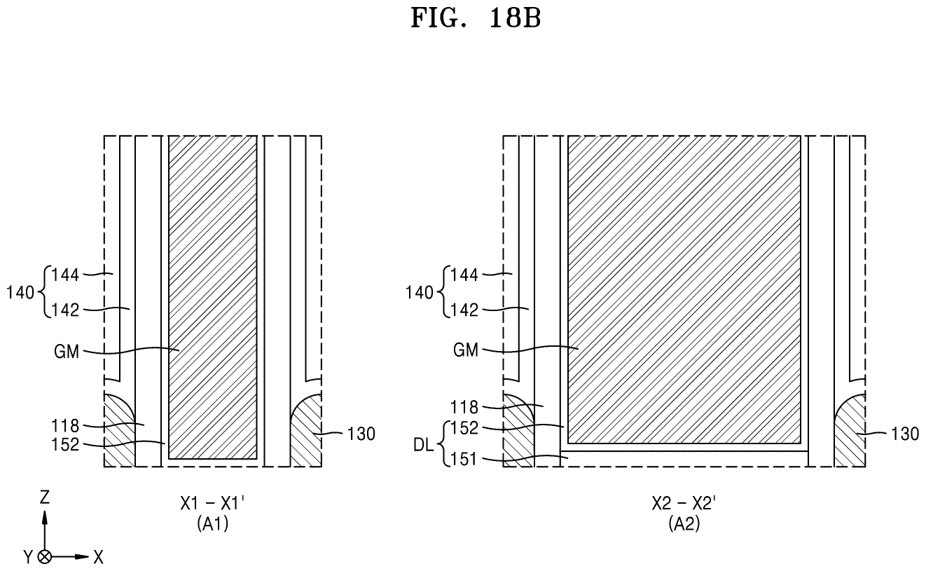

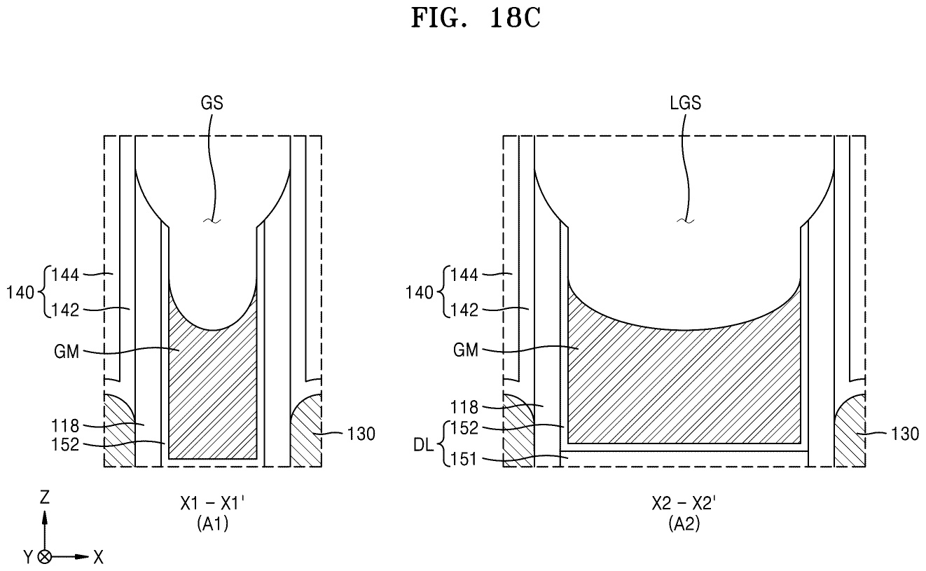

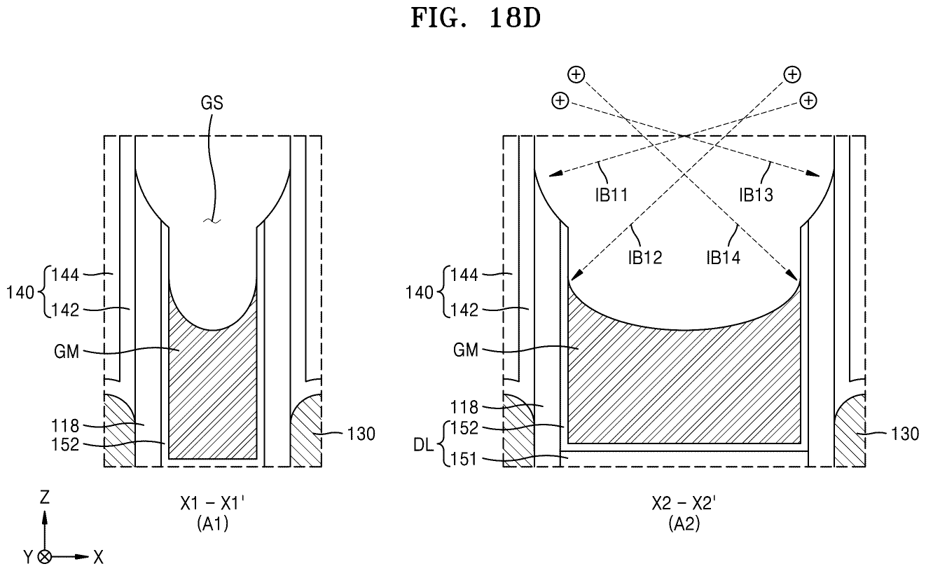

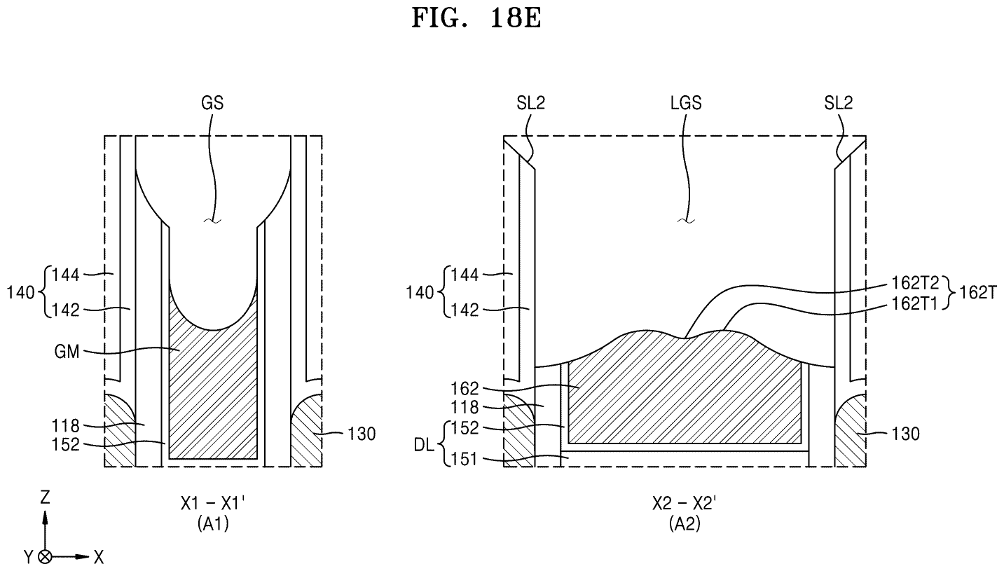

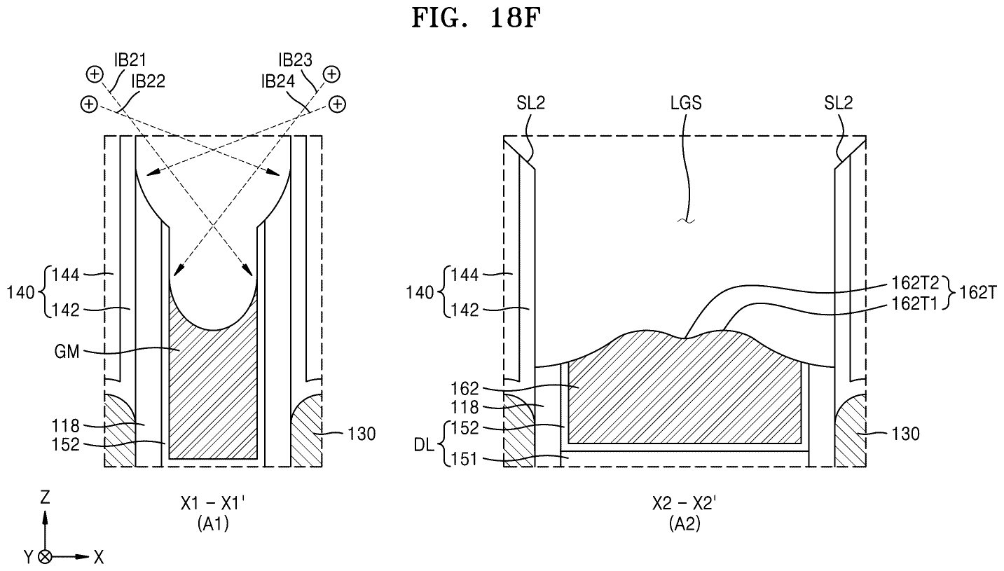

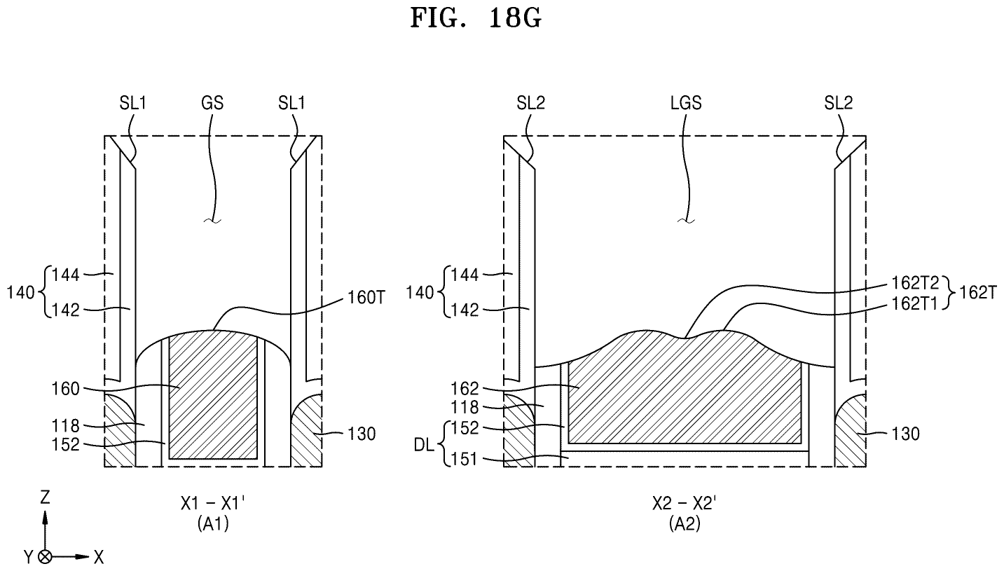

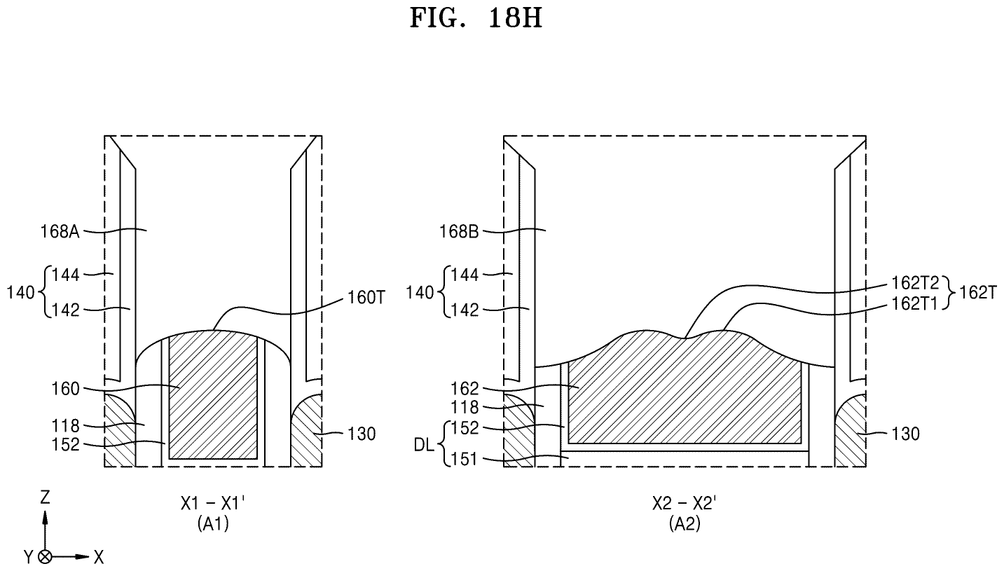

FIGS. 10A to 18H are cross-sectional views illustrating a sequence of processes of a method of fabricating an integrated circuit device, according to some embodiments. More specifically, FIGS. 10A, 11A, 12A, and 13 to 17 are cross-sectional views each illustrating an example of a cross-sectional structure of a portion of the integrated circuit device, which corresponds to the cross-section taken along the line X1-X1′ of FIG. 2, according to the sequence of processes. FIGS. 10B, 11B, and 12B are cross-sectional views each illustrating an example of a cross-sectional structure of a portion of the integrated circuit device, which corresponds to the cross-section taken along the line Y1-Y1′ of FIG. 2, according to the sequence of processes. FIGS. 18A to 18H are cross-sectional views respectively illustrating sequential processes of the process of FIG. 17 for more detailed descriptions of the process of FIG. 17. FIGS. 18A to 18H each illustrate enlarged cross-sectional configurations of portions of the integrated circuit device, which respectively correspond to the region EX1 of FIG. 3A and the region EX2 of FIG. 3C, according to the sequence of processes. An example of a method of fabricating the integrated circuit device 100 shown in FIGS. 1 to 4B is described with reference to FIGS. 10A to 18H. In FIGS. 10A to 18H, the same reference numerals as in FIGS. 1 to 4B may respectively denote the same members unless clearly stated otherwise, and here, repeated descriptions thereof may be omitted.

Referring to FIGS. 10A and 10B, in the first device area A1, a plurality of sacrificial semiconductor layers 104 and a plurality of nanosheet semiconductor layers NS may be alternately stacked one-by-one on the substrate 102.

The plurality of sacrificial semiconductor layers 104 and the plurality of nanosheet semiconductor layers NS may respectively include semiconductor materials having different etch selectivities from each other. In some embodiments, the plurality of nanosheet semiconductor layers NS may each include an Si layer and the plurality of sacrificial semiconductor layers 104 may each include an SiGe layer. In some embodiments, the amount of Ge may be constant in the plurality of sacrificial semiconductor layers 104. The SiGe layer constituting the plurality of sacrificial semiconductor layers 104 may include Ge in a constant amount selected from a range of (about) 5 at % to (about) 60 at %, for example, (about) 10 at % to (about) 40 at %. The amount of Ge in the SiGe layer, which constitutes the plurality of sacrificial semiconductor layers 104, may be variously selected as needed.

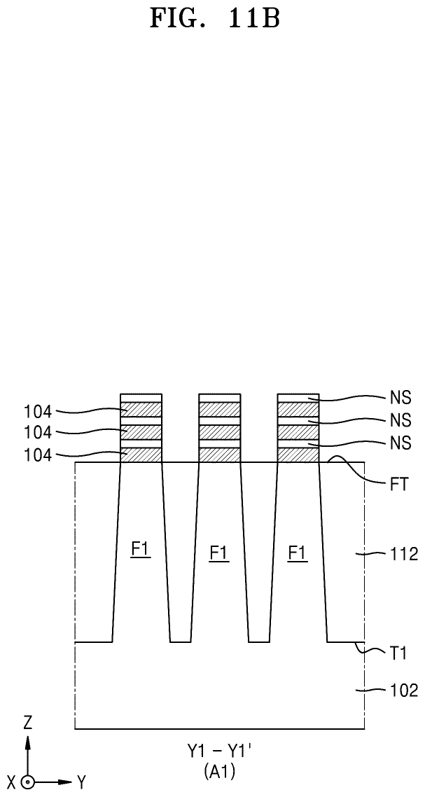

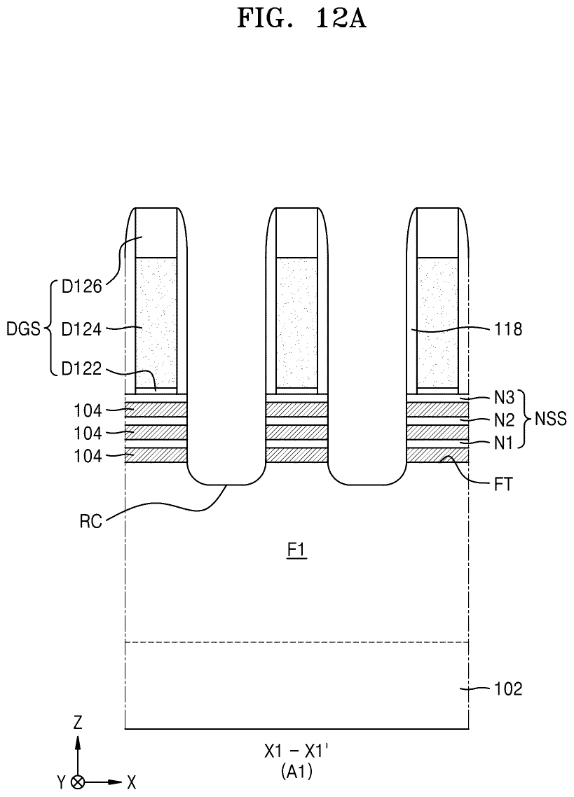

Referring to FIGS. 11A and 11B, in the resulting product of FIGS. 10A and 10B, the plurality of fin-type active regions F1, which protrude from the substrate 102, may be formed by partially etching the plurality of sacrificial semiconductor layers 104, the plurality of nanosheet semiconductor layers NS, and the substrate 102, and the device isolation film 112 may be formed to be on (e.g., cover at least a portion of or overlap) the sidewall of each of the plurality of fin-type active regions F1. A stack structure of the plurality of sacrificial semiconductor layers 104 and the plurality of nanosheet semiconductor layers NS may remain on the fin upper surface FT of each of the plurality of fin-type active regions F1.

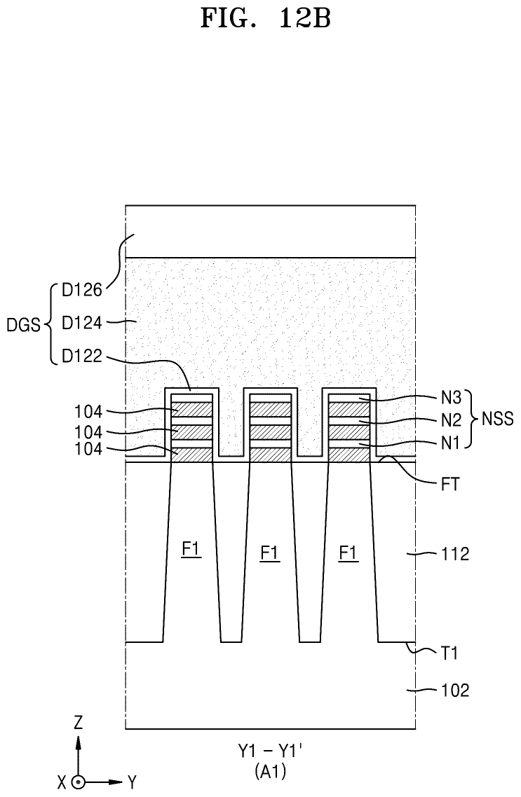

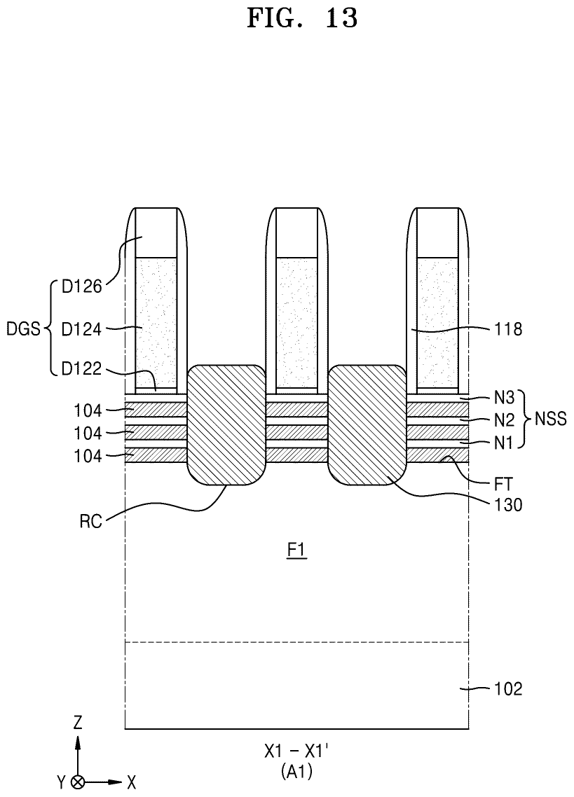

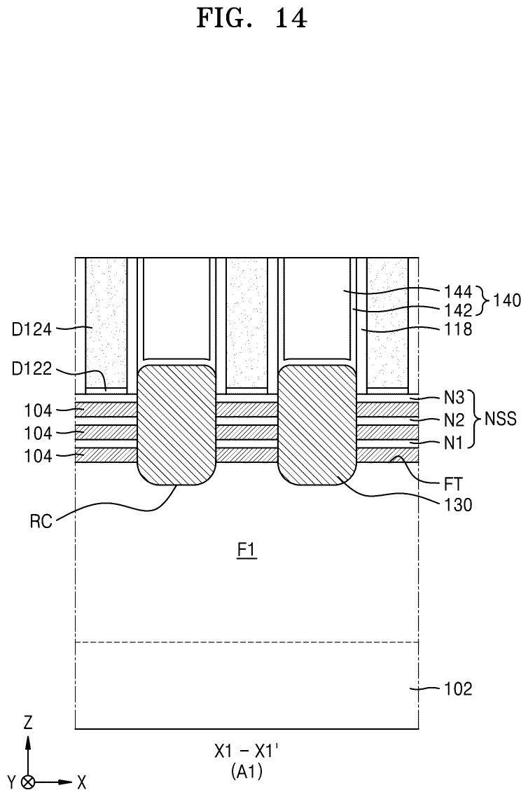

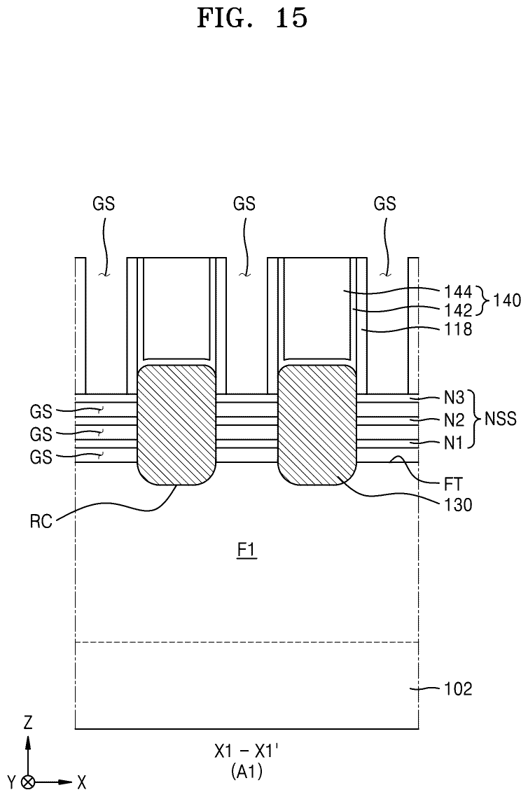

Referring to FIGS. 12A and 12B, a plurality of dummy gate structures DGS may be formed on the stack structure of the plurality of sacrificial semiconductor layers 104 and the plurality of nanosheet semiconductor layers NS.

Each of the plurality of dummy gate structures DGS may extend lengthwise in the second horizontal direction (e.g., the Y direction). Each of the plurality of dummy gate structures DGS may have a structure in which an oxide film D122, a dummy gate layer D124, and a capping layer D126 are stacked in the stated order. In some embodiments, the dummy gate layer D124 may include, for example, polysilicon and the capping layer D126 may include, for example, a silicon nitride film.

The plurality of insulating spacers 118 may be formed on (e.g., to cover at least a portion of or overlap) both (e.g., opposite) sidewalls of each of the plurality of dummy gate structures DGS, followed by etching a portion of each of the plurality of sacrificial semiconductor layers 104 and the plurality of nanosheet semiconductor layers NS and a portion of the fin-type active region F1 by using the plurality of dummy gate structures DGS and the plurality of insulating spacers 118 as an etch mask, thereby dividing the plurality of nanosheet semiconductor layers NS into the plurality of nanosheet stacks NSS and forming the plurality of recesses RC in an upper portion of the fin-type active region F1. Each of the plurality of nanosheet stacks NSS may include the first nanosheet N1, the second nanosheet N2, and the third nanosheet N3. To form the plurality of recesses RC, etching may be performed by using dry etching, wet etching, and/or a combination thereof.

Referring to FIG. 13, in the resulting product of FIGS. 12A and 12B, the plurality of source/drain regions 130 may be formed to (at least partially) fill the plurality of recesses RC, respectively.

To form the plurality of source/drain regions 130, a semiconductor material may be epitaxially grown on a surface of the fin-type active region F1, which is exposed at lower surfaces of the plurality of recesses RC, and on the sidewall of each of the first nanosheet N1, the second nanosheet N2, and the third nanosheet N3, which are included in the nanosheet stack NSS.

Referring to FIG. 14, the insulating structure 140 may be formed by sequentially forming the insulating liner 142 and the inter-gate dielectric 144 in the stated order to be on (e.g., to cover at least a portion of or overlap) the resulting product of FIG. 13, and then, the respective upper surfaces of a plurality of capping layers D126 may be exposed by partially etching the insulating structure 140. Next, the dummy gate layer D124 may be exposed by removing the plurality of capping layers D126, and the insulating structure 140 may be partially removed such that the upper surface of the insulating structure 140 is at a level (approximately) equal to that of the upper surface of the dummy gate layer D124.

Referring to FIG. 15, a gate space GS may be provided by removing the dummy gate layer D124 and the oxide film D122 under the dummy gate layer D124 from the resulting product of FIG. 14, and the plurality of nanosheet stacks NSS may be exposed by the gate space GS. Next, by removing the plurality of sacrificial semiconductor layers 104, which remain on the fin-type active region F1, through the gate space GS, the gate space GS may expand up to spaces between the first nanosheet N1, the second nanosheet N2, and the third nanosheet N3 and a space between the first nanosheet N1 and the fin upper surface FT of the fin-type active region F1. In some embodiments, to selectively remove the plurality of sacrificial semiconductor layers 104, the difference in etch selectivity between the plurality of sacrificial semiconductor layers 104 and each of the first nanosheet N1, the second nanosheet N2, and the third nanosheet N3 may be used.

To selectively remove the plurality of sacrificial semiconductor layers 104, a liquid and/or gaseous etchant may be used. In some embodiments, to selectively remove the plurality of sacrificial semiconductor layers 104, a CH3COOH-based etching solution, for example, an etching solution including a mixture of CH3COOH, HNO3, and HF, or an etching solution including a mixture of CH3COOH, H2O2, and HF, may be used, but the inventive concept is not limited thereto.

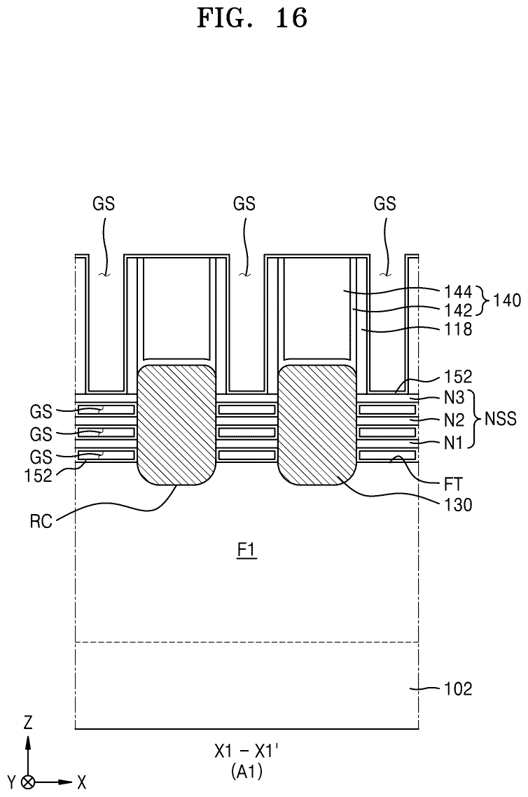

Referring to FIG. 16, in the resulting product of FIG. 15, the gate dielectric film 152 may be formed to be on (e.g., to cover at least a portion of or overlap) the respective exposed surfaces of the first nanosheet N1, the second nanosheet N2, the third nanosheet N3, and the fin-type active region F1. To form the gate dielectric film 152, a deposition process, such as an atomic layer deposition (ALD) process, may be used.

Referring to FIG. 17, the gate line 160 may be formed on the gate dielectric film 152 to (at least partially) fill the gate space GS (see FIG. 16) and to be on (e.g., to cover at least a portion of or overlap) the upper surface of the inter-gate dielectric 144, and then, the capping insulating pattern 168A may be formed to (at least partially) fill an upper portion of the gate space GS above the gate line 160.

While the processes described with reference to FIGS. 10A to 17 are performed in the first device area A1, similar processes to the processes in the first device area A1 may also be performed in the second device area A2. However, in the second device area A2, the processes required to form the plurality of nanosheet stacks NSS may be omitted, unlike in the first device area A1. In some embodiments, even in the second device area A2, the processes required to form the plurality of nanosheet stacks NSS may be performed, like in the first device area A1. In this case, instead of the field-effect transistor TR2 having the structure shown in FIG. 3C, a plurality of field-effect transistors each having a gate-all-around structure, such as the field-effect transistor TR1 shown in FIG. 3A and formed in the first device area A1, may also be obtained even in the second device area A2.

Processes of forming the gate line 160 and the capping insulating pattern 168A in the first device area A1, as described with reference to FIG. 17, and processes of forming the gate line 162 and the capping insulating pattern 168B in the second device area A2 are described in more detail with reference to FIGS. 18A to 18H.

After the processes described with reference to FIGS. 10A to 16 are performed, as shown in FIG. 18A, a result product, in which the gate dielectric film 152 is formed in the gate space GS, may be obtained in the first device area A1 and a result product, in which a multi-gate dielectric film DL having a stack structure of the interface dielectric film 151 and the gate dielectric film 152 is formed in a gate space LGS, may be obtained in the second device area A2.

Referring to FIG. 18B, in the resulting product of FIG. 18A, the gate space GS in the first device area A1 and the gate space LGS in the second device area A2 may be (at least partially) filled with a gate conductive layer GM. A constituent material of the gate conductive layer GM may be the same as the constituent material of the gate line 160 described above.

Referring to FIG. 18C, portions of the gate conductive layer GM in the first device area A1 and the second device area A2 may be selectively removed by a vertical anisotropic etching process, thereby emptying a portion of each of the gate space GS in the first device area A1 and the gate space LGS in the second device area A2 again. For example, the gate conductive layer GM may be removed to expose a portion (e.g., an upper portion) of the gate space GS in the first device area A1 and the gate space LGS in the second device area A2.

In some embodiments, in the vertical anisotropic etching process, ion collision with the gate conductive layer GM in the vertical direction (e.g., the Z direction) may be induced in a plasma etching atmosphere including reactive radicals, for example, Cl radicals, and Ar ions, thereby removing the portions of the gate conductive layer GM. In some embodiments, to perform the vertical anisotropic etching process, an induced coupled plasma (ICP) etching process, in which high-density plasma is formed in the manner of forming an induced electric field by using a magnetic field, may be used, but the inventive concept is not limited thereto.

While the portions of the gate conductive layer GM are removed in the process of FIG. 18C, a portion of the insulating structure 140, which is adjacent to the entrance of each of the gate spaces GS and LGS, may be consumed, the insulating structure 140, including the insulating liner 142 and the inter-gate dielectric 144.

Referring to FIG. 18D, to remove two side portions (e.g., opposite side portions in the first horizontal direction (e.g., the X direction)) of the gate conductive layer GM, which are adjacent to the gate dielectric film 152, in the second device area A2 from the resulting product of FIG. 18C, an etching process in an inclined direction (hereinafter, referred to as a tilted etching process) may be performed.

To perform a tilted etching process according to the process of FIG. 18D, an etching process using an ion beam (hereinafter, referred to as an ion beam etching process) may be performed. The ion beam etching process for removing the two side portions of the gate conductive layer GM may be an ion beam etching process using a reactive gas, for example, a chlorine-based gas, as an ion source. In the ion beam etching process, Ar, in addition to the chlorine-based gas, may be additionally used as the ion source. The chlorine-based gas may include, but is not limited to, Cl2.

While the two side portions of the gate conductive layer GM are removed, a portion of the gate dielectric film 152 and a portion of the insulating spacer 118, which are exposed by the gate space LGS, may also be removed. In some embodiments, to effectively remove the portion of the gate dielectric film 152 and the portion of the insulating spacer 118, an ion source obtained from a fluorine-based gas may be added in the ion beam etching process. The fluorine-based gas may include, but is not limited to, a fluorocarbon-based gas, such as CF4, C2F6, C3F8, C4F6, or C4F8 gas.

In some embodiments, to remove the two side portions of the gate conductive layer GM and the respective portions of the gate dielectric film 152 and the insulating spacer 118, which are exposed by the gate space LGS, by the ion beam etching process, the ion beam etching process may be performed while gradually rotating an ion beam incidence direction from a direction along the dashed arrow IB11 in FIG. 18D to a direction along the dashed arrow IB12 in FIG. 18D or from the direction along the dashed arrow IB12 to the direction along the dashed arrow IB11, and thus, a tilted etching process may be performed on one side of the gate conductive layer GM, which is exposed by the gate space LGS, in terms of the first horizontal direction (e.g., the X direction). In addition, the ion beam etching process may be performed while gradually rotating the ion beam incidence direction from a direction along the dashed arrow IB13 in FIG. 18D to a direction along the dashed arrow IB14 in FIG. 18D or from the direction along the dashed arrow IB14 to the direction along the dashed arrow IB13, and thus, a tilted etching process may be performed on the other side of the gate conductive layer GM, which is exposed by the gate space LGS, in terms of the first horizontal direction (e.g., the X direction). Here, the order of etching the one side and the other side of the gate conductive layer GM in terms of the first horizontal direction (e.g., the X direction) is not particularly limited and may be arbitrarily determined. Also, the angles, numbers, changing, and on/off of the directions of the ion beam incidence are not particularly limited to the descriptions above and may be arbitrarily determined.

As a result of performing the ion beam etching process described above with reference to FIG. 18D, the gate line 162, which has a gate upper surface 162T that is (generally) convex upwards in the vertical direction (e.g., the Z direction), may be formed and the insulating structure 140 may have an inclined surface SL2 in a portion thereof adjacent to the entrance of the gate space LGS, as shown in FIG. 18E.

Referring to FIG. 18F, to remove two side portions (e.g., opposite side portions in the first horizontal direction (e.g., the X direction)) of the gate conductive layer GM, which are adjacent to the gate dielectric film 152, in the first device area A1 from the resulting product of FIG. 18E, a tilted etching process may be performed.

To perform a tilted etching process according to the process of FIG. 18F, a similar process to the ion beam etching process, which is described with reference to FIG. 18D, in the first device area A1 may be performed. In the first device area A1, while the two side portions of the gate conductive layer GM are removed, a portion of the gate dielectric film 152 and a portion of the insulating spacer 118, which are exposed by the gate space GS, may also be removed.

In some embodiments, in the first device area A1, to remove the two side portions of the gate conductive layer GM and the respective portions of the gate dielectric film 152 and the insulating spacer 118, which are exposed by the gate space GS, by the ion beam etching process, the ion beam etching process may be performed while gradually rotating an ion beam incidence direction from a direction along the dashed arrow IB21 in FIG. 18F to a direction along the dashed arrow IB22 in FIG. 18D or from the direction along the dashed arrow IB22 to the direction along the dashed arrow IB21, and thus, a tilted etching process may be performed on one side of the gate conductive layer GM, which is exposed by the gate space GS, in terms of the first horizontal direction (e.g., the X direction). In addition, the ion beam etching process may be performed while gradually rotating the ion beam incidence direction from a direction along the dashed arrow IB23 in FIG. 18F to a direction along the dashed arrow IB24 in FIG. 18F or from the direction along the dashed arrow IB24 to the direction along the dashed arrow IB23, and thus, a tilted etching process may be performed on the other side of the gate conductive layer GM, which is exposed by the gate space GS, in terms of the first horizontal direction (e.g., the X direction). Here, the order of etching the one side and the other side of the gate conductive layer GM in terms of the first horizontal direction (e.g., the X direction) is not particularly limited and may be arbitrarily determined. Also, the angles, numbers, changing, and on/off of the directions of the ion beam incidence are not particularly limited to the descriptions above and may be arbitrarily determined.

As a result of performing the ion beam etching process described above with reference to FIG. 18F, the gate line 160, which has a gate upper surface 160T that is (generally) convex upwards in the vertical direction (e.g., the Z direction), may be formed and the insulating structure 140 may have an inclined surface SL1 in a portion thereof adjacent to the entrance of the gate space GS, as shown in FIG. 18G.

Referring to FIG. 18H, in the resulting product of FIG. 18G, the capping insulating patterns 168A and 168B may be respectively formed to (at least partially) fill portions of the gate spaces GS and LGS, which respectively remain above the gate lines 160 and 162.

Next, a capping insulating pattern 168 may be formed to (at least partially) fill the remaining portions of the gate space GS and to be on (e.g., to cover at least a portion of or overlap) the upper surface (e.g., the upper surface 160T and 162T) of the gate lines 160 and 162 to form the capping insulating patterns 168A and 168B. Next, in the first device area A1 and the second device area A2, the insulating structure 140 including the insulating liner 142 and the inter-gate dielectric 144 may be etched, thereby forming a plurality of source/drain contact holes, which each expose the source/drain region 130. Because each of the capping insulating patterns 168A and 168B includes a material that is difficult to etch in the etching process atmosphere, for example, a silicon nitride film, and the pair of side insulating portions SD1 or SD2 respectively cover (at least a portion of) both (e.g., opposite) side upper portions of the gate line 160 or 162 up to a level that is lower than that of the uppermost portion of the gate line 160 or 162, while the insulating structure 140 is etched to form the plurality of source/drain contact holes, the gate lines 160 and 162 may be protected respectively by the capping insulating patterns 168A and 168B and thus not be exposed to the etching process atmosphere.

A portion of the source/drain region 130 may be removed through each of the plurality of source/drain contact holes by an anisotropic etching process, and the metal silicide film 172 may be formed on the source/drain region 130 that is exposed at the lower surface of each of the plurality of source/drain contact holes. Next, as shown in FIGS. 3A to 3C, the source/drain contact CA may be formed by (at least partially) filling the inside of each of the plurality of source/drain contact holes with the conductive barrier film 174 and the contact plug 176. After the source/drain contact CA is formed, because the side insulating portion SD1 or SD2 of each of the capping insulating patterns 168A and 168B is arranged between the source/drain contact CA and the gate line 160 or 162 adjacent to the source/drain contact CA, (unintended or defective) parasitic capacitance between the source/drain contact CA and each of the gate lines 160 and 162 may be reduced and the possibility of an untended short-circuit between the source/drain contact CA and each of the gate lines 160 and 162 may be reduced (e.g., removed).

The first upper insulating structure 181 may be formed on a result product in which the source/drain contact CA is formed, and then, the gate contact CB and the plurality of via contacts VA may be formed. Next, the second upper insulating structure 185 may be formed, followed by forming the plurality of upper wiring layers M1 in (through) the second upper insulating structure 185, thereby fabricating the integrated circuit device 100 that has the structure described with reference to FIGS. 1 to 4B.

Heretofore, while the example of the method of fabricating the integrated circuit device 100 described with reference to FIGS. 1 to 4B has been described with reference to FIGS. 10A to 18H, it will be understood by those of ordinary skill in the art that, by making various modifications and changes to the example described with reference to FIGS. 1 to 4B without departing from the scope of the inventive concept, the integrated circuit devices 200, 300, 400, 500, and 600 shown in FIGS. 5 to 9 and integrated circuit devices having various structures modified and changed therefrom may be fabricated. For example, various structures of the gate upper surface 160T, 162T, 360T, 562T, or 662T of the gate line 160, 162, 360, 562, or 662, which is included in the integrated circuit device 200, 300, 400, 500, or 600 shown in FIGS. 5 to 9, and the inclined surfaces SL1 and SL2 of the insulating structure 140 may be obtained by variously modifying an inclination direction, an inclination angle, or the like of an ion beam in the ion beam etching process described with reference to FIGS. 18D and 18F.

While the inventive concept has been particularly shown and described with reference to embodiments thereof, it will be understood that various changes in form and details may be made therein without departing from the scope of the following claims.

What is claimed is:

1. An integrated circuit device comprising:
a substrate;
a fin-type active region that extends in a first horizontal direction on the substrate;
a gate line on the fin-type active region, wherein the gate line extends in a second horizontal direction that intersects the first horizontal direction; and
a gate dielectric film that is in contact with a lower surface and opposite sidewalls of the gate line,
wherein a gate upper surface of the gate line includes a portion that has a decreasing distance from the substrate in a vertical direction as a distance between the portion of the gate upper surface of the gate line and the gate dielectric film in the first horizontal direction decreases.

2. The integrated circuit device of claim 1, further comprising:
a capping insulating pattern that has a capping lower surface that is in contact with the gate upper surface of the gate line and an upper surface of the gate dielectric film,
wherein the capping lower surface of the capping insulating pattern includes a portion that has a decreasing distance from the substrate in the vertical direction as a distance between the capping lower surface of the capping insulating pattern and the gate dielectric film in the first horizontal direction decreases.

3. The integrated circuit device of claim 1, further comprising:
a pair of insulating spacers respectively on the opposite sidewalls of the gate line; and
a capping insulating pattern that has a capping lower surface that is in contact with the gate upper surface of the gate line, an upper surface of the gate dielectric film, and upper surfaces of the pair of insulating spacers,
wherein the capping lower surface of the capping insulating pattern includes a portion that has a decreasing distance from the substrate in the vertical direction as a distance between the capping lower surface of the capping insulating pattern and each of the pair of insulating spacers in the first horizontal direction decreases.

4. The integrated circuit device of claim 1, further comprising:
a capping insulating pattern that has a capping lower surface that is in contact with the gate upper surface of the gate line and an upper surface of the gate dielectric film,
wherein the capping insulating pattern comprises:
a center insulating portion that overlaps the gate line in the vertical direction; and
a pair of side insulating portions that are integrally connected with the center insulating portion and each face the gate line at a distance that is closer than the gate upper surface of the gate line to the substrate.

5. The integrated circuit device of claim 4, wherein respective lowermost portions of the pair of side insulating portions are equidistant from the substrate, and the pair of side insulating portions are symmetrical with each other about the gate line.

6. The integrated circuit device of claim 4, wherein respective lowermost portions of the pair of side insulating portions are at different distances from the substrate, and the pair of side insulating portions are asymmetric with each other about the gate line.

7. The integrated circuit device of claim 1, further comprising:
a capping insulating pattern that is in contact with the gate upper surface of the gate line and an upper surface of the gate dielectric film;
a source/drain region on the fin-type active region, wherein the source/drain region is adjacent to the gate line in the first horizontal direction;
an insulating structure on the source/drain region; and
a source/drain contact that extends in the insulating structure in the vertical direction to be electrically connected to the source/drain region,
wherein a portion of the gate line faces the source/drain contact in the first horizontal direction, and
wherein the capping insulating pattern includes a portion between the gate line and the source/drain contact in the first horizontal direction.

8. The integrated circuit device of claim 1, further comprising:
a gate contact that is on and electrically connected to the gate line,
wherein the gate line has a portion that is convex toward the gate contact.

9. The integrated circuit device of claim 1, further comprising:
a capping insulating pattern that has a capping lower surface and a capping upper surface,
wherein the capping lower surface and the capping upper surface are opposite to each other in the vertical direction,
wherein the capping lower surface is in contact with the gate upper surface of the gate line and an upper surface of the gate dielectric film, and
wherein the capping insulating pattern includes a protrusion that is adjacent to the capping upper surface and protrude outwards in the first horizontal direction.

10. An integrated circuit device comprising:
a substrate that includes a first device area and a second device area;
a first fin-type active region on the substrate in the first device area, wherein the first fin-type active region extends in a first horizontal direction;
a first gate line on the first fin-type active region, wherein the first gate line extends in a second horizontal direction that intersects the first horizontal direction, and wherein the first gate line has a first width in the first horizontal direction;
a first gate dielectric film that is in contact with a lower surface and opposite sidewalls of the first gate line;
a second fin-type active region on the substrate in the second device area, wherein the second fin-type active region extends in the first horizontal direction;
a second gate line on the second fin-type active region, wherein the second gate line extends in the second horizontal direction, and wherein the second gate line has a second width that is greater in the first horizontal direction than the first width of the first gate line; and
a second gate dielectric film that is in contact with a lower surface and opposite sidewalls of the second gate line,
wherein a first gate upper surface of the first gate line includes a portion that has a decreasing distance from the substrate in a vertical direction as a distance between the portion of the first gate upper surface of the first gate line and the first gate dielectric film in the first horizontal direction decreases, and
wherein a second gate upper surface of the second gate line includes a portion that has a decreasing distance from the substrate in the vertical direction as a distance between the portion of the second gate upper surface of the second gate line and the second gate dielectric film in the first horizontal direction decreases.

11. The integrated circuit device of claim 10, wherein an uppermost portion of the second gate upper surface is at a center point of the second gate upper surface in the first horizontal direction.

12. The integrated circuit device of claim 10, wherein an uppermost portion of the second gate upper surface is at a position biased to one side in the first horizontal direction from a center point of the second gate upper surface in the first horizontal direction.

13. The integrated circuit device of claim 10, further comprising:
a pair of first insulating spacers on the opposite sidewalls of the first gate line;
a first capping insulating pattern that has a first capping lower surface that is in contact with the first gate upper surface of the first gate line, an upper surface of the first gate dielectric film, and upper surfaces of the pair of first insulating spacers;
a pair of second insulating spacers on the opposite sidewalls of the second gate line; and
a second capping insulating pattern that has a second capping lower surface that is in contact with the second gate upper surface of the second gate line, an upper surface of the second gate dielectric film, and upper surfaces of the pair of second insulating spacers,
wherein the first capping lower surface of the first capping insulating pattern includes a portion that has a decreasing distance from the substrate in the vertical direction as a distance between the portion of the first capping lower surface of the first capping insulating pattern and each of the pair of first insulating spacers in the first horizontal direction decreases, and
wherein the second capping lower surface of the second capping insulating pattern includes a portion that has a decreasing distance from the substrate in the vertical direction as a distance between the portion of the second capping lower surface of the second capping insulating pattern and each of the pair of second insulating spacers in the first horizontal direction decreases.

14. The integrated circuit device of claim 13, wherein the first capping insulating pattern comprises:
a first center insulating portion that overlaps the first gate line in the vertical direction; and
a pair of first side insulating portions that are integrally connected with the first center insulating portion and each face the first gate line at a distance that is closer than the first gate upper surface of the first gate line to the substrate,
the second capping insulating pattern comprises:
a second center insulating portion that overlaps the second gate line in the vertical direction; and
a pair of second side insulating portions that are integrally connected with the second center insulating portion and each face the second gate line at a distance that is closer than the second gate upper surface of the second gate line to the substrate,
wherein the pair of first side insulating portions are symmetrical with each other about the first gate line, and
wherein the pair of second side insulating portions are symmetrical with each other about the second gate line.

15. The integrated circuit device of claim 13, wherein the first capping insulating pattern comprises:
a first center insulating portion that overlaps the first gate line in the vertical direction; and
a pair of first side insulating portions that are integrally connected with the first center insulating portion and each face the first gate line at a distance that is closer than the first gate upper surface of the first gate line to the substrate,
the second capping insulating pattern comprises:
a second center insulating portion that overlaps the second gate line in the vertical direction; and
a pair of second side insulating portions that are integrally connected with the second center insulating portion and each face the second gate line at a distance that is closer than the second gate upper surface of the second gate line to the substrate, and
wherein the pair of first side insulating portions are asymmetrical with each other, and/or the pair of second side insulating portions are asymmetrical with each other.

16. The integrated circuit device of claim 10, further comprising:
a first capping insulating pattern on the first gate upper surface of the first gate line; and
a second capping insulating pattern on the second gate upper surface of the second gate line,
wherein at least one of the first capping insulating pattern and the second capping insulating pattern has an upper portion that protrudes outwards in the first horizontal direction.

17. The integrated circuit device of claim 10, further comprising:
a first capping insulating pattern on the first gate upper surface of the first gate line;
a first source/drain region on the first fin-type active region, wherein the first source/drain region is adjacent to the first gate line in the first horizontal direction; and
a first source/drain contact on the first source/drain region, wherein the first source/drain contact is electrically connected to the first source/drain region,
wherein the first capping insulating pattern includes a portion between the first gate line and the first source/drain contact in the first horizontal direction.

18. The integrated circuit device of claim 10, further comprising:
a second capping insulating pattern on the second gate upper surface of the second gate line;
a second source/drain region on the second fin-type active region, wherein the second source/drain region is adjacent to the second gate line in the first horizontal direction; and
a second source/drain contact on the second source/drain region, wherein the second source/drain contact is electrically connected to the second source/drain region,
wherein the second capping insulating pattern includes a portion between the second gate line and the second source/drain contact in the first horizontal direction.

19. An integrated circuit device comprising:
a substrate;
a fin-type active region that extends in a first horizontal direction on the substrate;
a nanosheet stack on a fin upper surface of the fin-type active region, wherein the nanosheet stack is spaced apart from the fin upper surface in a vertical direction, and wherein the nanosheet stack includes at least one nanosheet;
a gate line on the fin-type active region, wherein the gate line extends around the at least one nanosheet, wherein the gate line extends in a second horizontal direction;
a gate dielectric film that is in contact with a lower surface and opposite sidewalls of the gate line;
a pair of insulating spacers on the opposite sidewalls of the gate line, wherein the pair of insulating spacers are each spaced apart from the gate line in the first horizontal direction with the gate dielectric film therebetween; and
a capping insulating pattern that includes a capping lower surface, wherein the capping lower surface is in contact with a gate upper surface of the gate line, an upper surface of the gate dielectric film, and upper surfaces of the pair of insulating spacers,
wherein the gate upper surface of the gate line includes a portion that has a decreasing distance from the substrate in the vertical direction as a distance between the portion of the gate upper surface of the gate line and each of the pair of insulating spacers in the first horizontal direction decreases, and
wherein the capping insulating pattern includes a center insulating portion that overlaps the gate line in the vertical direction and a pair of side insulating portions that are integrally connected with the center insulating portion and each face the gate line at a distance that is closer than the gate upper surface of the gate line to the substrate.

20. The integrated circuit device of claim 19, further comprising:
a source/drain region on the fin-type active region, wherein the source/drain region is adjacent to the gate line in the first horizontal direction; and
a source/drain contact on the source/drain region, wherein the source/drain contact is electrically connected to the source/drain region,
wherein the source/drain contact faces the gate line in the first horizontal direction, and
wherein the capping insulating pattern includes a portion between the gate line and the source/drain contact in the first horizontal direction.
